(19) United States
(12) Patent Application Publication
(10) Pub. No.: US 2025/0120283 A1
(43) Pub. Date: Apr. 10, 2025

(54) LIGHT EMITTING DEVICE, DISPLAY DEVICE, AND ELECTRONIC DEVICE

(71) Applicants: Sony Group Corporation, Tokyo (JP); Sony Semiconductor Solutions Corporation, Kanagawa (JP)

(72) Inventors: Yu Kato, Kanagawa (JP); Naoya Kasahara, Kanagawa (JP); Tomoaki Sawabe, Kanagawa (JP); Takashi Yamazaki, Kanagawa (JP)

(21) Appl. No.: 18/281,864

(22) PCT Filed: Mar. 16, 2022
(86) PCT No.: PCT/JP2022/011786

§ 371 Date: Sep. 13, 2023

(30) Foreign Application Priority Data
Mar. 31, 2021 (JP) 2021-061659

(51) Int. Cl. H10K 59/80

(52) U.S. Cl. CPC H10K 59/80522; H10K 59/80515

(57) ABSTRACT

Light emitting devices and display devices with improved aperture ratio and suppressed current leakage between electrodes are disclosed. In one example, a light emitting device includes a substrate, a laminated structure, and an electrode relay portion. The laminated structure includes first through third electrodes and first and second organic layers. The second electrode is a common electrode corresponding to the first and third electrodes. A wall surface portion includes a connecting surface in which a sidewall of the first organic layer, a sidewall of the second electrode, and a sidewall of the second organic layer are connected. A sidewall insulating layer covers at least a part of the wall surface portion, and the electrode relay portion extends from the third electrode toward the substrate, and passes over an outer surface of the wall surface portion via the sidewall insulating layer.

### TECHNICAL FIELD

The present disclosure relates to a light emitting device, a display device, and an electronic device using the display device.

### BACKGROUND ART

As a light emitting device (organic EL light emitting device) or the like using an organic EL element as a light emitting element, a multistage stacked device in which a plurality of structures for forming subpixels is stacked is known.

For example, Patent Document 1 proposes a display device having a structure in which a first electrode, a first organic layer, a second electrode, a second organic layer, and a third electrode are sequentially laminated on a substrate in a state where positions of respective end portions are shifted. In addition, Patent Document 2 proposes a display device having a structure in which a first electrode, a first organic layer, a second electrode, a second organic layer, and a third electrode are laminated on a substrate, end portions of some layers are aligned, and the first electrode and the third electrode are connected.

### CITATION LIST

### Patent Document

Patent Document 1: Japanese Patent Application Laid-Open No. 2010-123286
Patent Document 2: Japanese Patent Application Laid-Open No. 2005-4062

### SUMMARY OF THE INVENTION

### Problems to be Solved by the Invention

In the display device as disclosed in Patent Document 1, there is room for improvement in terms of suppressing a problem that it is difficult to improve the aperture ratio of the subpixels. In the display device as illustrated in Patent Document 2, there is room for improvement in terms of suppressing current leakage between electrodes at the position of the end portion.

The present disclosure has been made in view of the above-described points, and an object of the present disclosure is to provide a light emitting device, a display device, and an electronic device using the display device, which are capable of improving an aperture ratio and excellent in suppressing current leakage between electrodes.

### Solutions to Problems

The present disclosure is a light emitting device including: for example:
(1) a substrate;
a laminated structure; and
an electrode relay portion,
in which the laminated structure includes a first electrode, a first organic layer, a second electrode, a second organic layer, and a third electrode in this order on the substrate,
the second electrode is a common electrode corresponding to the first electrode and the third electrode,
a wall surface portion is formed, the wall surface portion including, at least in part, a connecting surface in which a sidewall of the first organic layer, a sidewall of the second electrode, and a sidewall of the second organic layer are connected,
a sidewall insulating layer covering at least a part of the wall surface portion is provided, and
the electrode relay portion extends from the third electrode toward the substrate, and passes over an outer surface of the wall surface portion via the sidewall insulating layer.

The present disclosure is a light emitting device including:
(2) a substrate;
a laminated structure;
a first electrode relay portion; and
a second electrode relay portion,
in which the laminated structure includes a first electrode, a first organic layer, a second electrode, a second organic layer, a third electrode, a fourth electrode, a third organic layer, and a fifth electrode
in this order on the substrate, the second electrode is a common electrode corresponding to the first electrode and the third electrode,
a wall surface portion is formed, the wall surface portion including, at least in a part, a connecting surface formed by connecting a sidewall of the first organic layer, a sidewall of the second electrode, and a sidewall of the second organic layer, and an alignment surface formed by arranging at least a sidewall of the fourth electrode and a sidewall of the third organic layer along a surface direction of the connecting surface,
a sidewall insulating layer is provided on the wall surface portion,
the first electrode relay portion extends from the third electrode to the substrate,
the second electrode relay portion extends from the fourth electrode toward the substrate, and
the first electrode relay portion and the second electrode relay portion pass over an outer surface of the wall surface portion via the sidewall insulating layer.

The present disclosure is a light emitting device including:
(3) a substrate;
a laminated structure; and
an electrode relay portion,
in which the laminated structure includes a first electrode, a first organic layer, a charge generation layer, a second organic layer, and a second electrode in this order on the substrate,
a wall surface portion is formed, the wall surface portion including, at least in part, a connecting surface in which a sidewall of the first organic layer, a sidewall of the charge generation layer, and a sidewall of the second organic layer are connected,
a sidewall insulating layer is provided on the wall surface portion, and
the electrode relay portion extends from the second electrode to the substrate and passes over an outer surface of the wall surface portion via the sidewall insulating layer.

Further, the present disclosure is a display device including
(4) the light emitting device according to (1).

Further, the present disclosure may be an electronic device including
(5) the display device according to (4).

### BRIEF DESCRIPTION OF DRAWINGS

FIG. 1 is a plan view for explaining an example of a display device according to a first embodiment.

FIG. 2 is a plan view for explaining an arrangement of pixels of the display device according to the first embodiment.

FIG. 3 is a cross-sectional view illustrating a state of a longitudinal cross section taken along line A1-A1 in FIG. 2.

FIG. 4 is a cross-sectional view illustrating a state of a longitudinal cross section taken along line A2-A2 in FIG. 2.

FIGS. 5A to 5D are plan views for explaining each layer of the display device according to the first embodiment.

FIGS. 6A to 6D are plan views for explaining each layer of the display device according to the first embodiment.

FIGS. 7A and 7B are cross-sectional views for explaining an auxiliary electrode of the display device according to the first embodiment.

FIG. 8 is a cross-sectional view for explaining a modification of the display device according to the first embodiment.

FIG. 9 is a cross-sectional view for explaining a modification of the display device according to the first embodiment.

FIG. 10 is a cross-sectional view for explaining a modification of the display device according to the first embodiment.

FIG. 11 is a cross-sectional view for explaining a modification of the display device according to the first embodiment.

FIG. 12 is a plan view for explaining an arrangement of pixels of a display device according to a second embodiment.

FIG. 13 is a cross-sectional view illustrating a state of a longitudinal cross section taken along line B1-B1 in FIG. 12.

FIG. 14 is a cross-sectional view illustrating a state of a longitudinal cross section taken along line B2-B2 in FIG. 12.

FIGS. 15A to 15E are plan views for explaining each layer of the display device according to the second embodiment.

FIGS. 16A to 16E are plan views for explaining each layer of the display device according to the second embodiment.

FIG. 17 is a plan view for explaining an arrangement of pixels of a display device according to a third embodiment.

FIG. 18 is a cross-sectional view illustrating a state of a longitudinal cross section taken along line C1-C1 in FIG. 17.

FIG. 19 is a cross-sectional view illustrating a state of a longitudinal cross section taken along line C2-C2 in FIG. 17.

FIGS. 20A to 20F are plan views for explaining each layer of the display device according to the second embodiment.

FIG. 21 is a cross-sectional view illustrating the method of manufacturing the display device according to the first embodiment.

FIG. 22 is a cross-sectional view illustrating the method of manufacturing the display device according to the first embodiment.

FIG. 23 is a cross-sectional view illustrating the method of manufacturing the display device according to the first embodiment.

FIG. 24 is a cross-sectional view illustrating the method of manufacturing the display device according to the first embodiment.

FIG. 25 is a cross-sectional view illustrating the method of manufacturing the display device according to the first embodiment.

FIG. 26 is a cross-sectional view illustrating the method of manufacturing the display device according to the first embodiment.

FIG. 27 is a cross-sectional view illustrating the method of manufacturing the display device according to the first embodiment.

FIG. 28 is a cross-sectional view illustrating the method of manufacturing the display device according to the first embodiment.

FIG. 29 is a plan view illustrating the method of manufacturing the display device according to the first embodiment.

FIG. 30 is a cross-sectional view illustrating the method of manufacturing the display device according to the first embodiment.

FIG. 31 is a cross-sectional view illustrating the method of manufacturing the display device according to the first embodiment.

FIG. 32 is a cross-sectional view illustrating the method of manufacturing the display device according to the first embodiment.

FIGS. 33A and 33B are diagrams for explaining an example of an electronic device using a display device.

FIG. 34 is a diagram for explaining an example of an electronic device using a display device.

FIG. 35 is a diagram for explaining an example of an electronic device using a display device.

### MODE FOR CARRYING OUT THE INVENTION

Hereinafter, an example and the like according to the present disclosure will be described with reference to the drawings. Note that, the description will be made in the following order. In the present specification and the drawings, configurations having substantially the same functional configurations are denoted by the same reference numerals, and redundant descriptions are omitted.

Note that, the description will be given in the following order.
1. First Embodiment
2. Second Embodiment
3. Third Embodiment
4. Manufacturing Method
5. Application Example (Electronic Device)

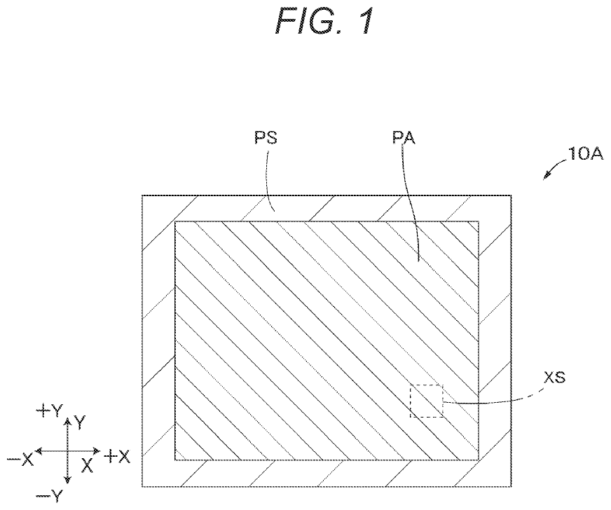

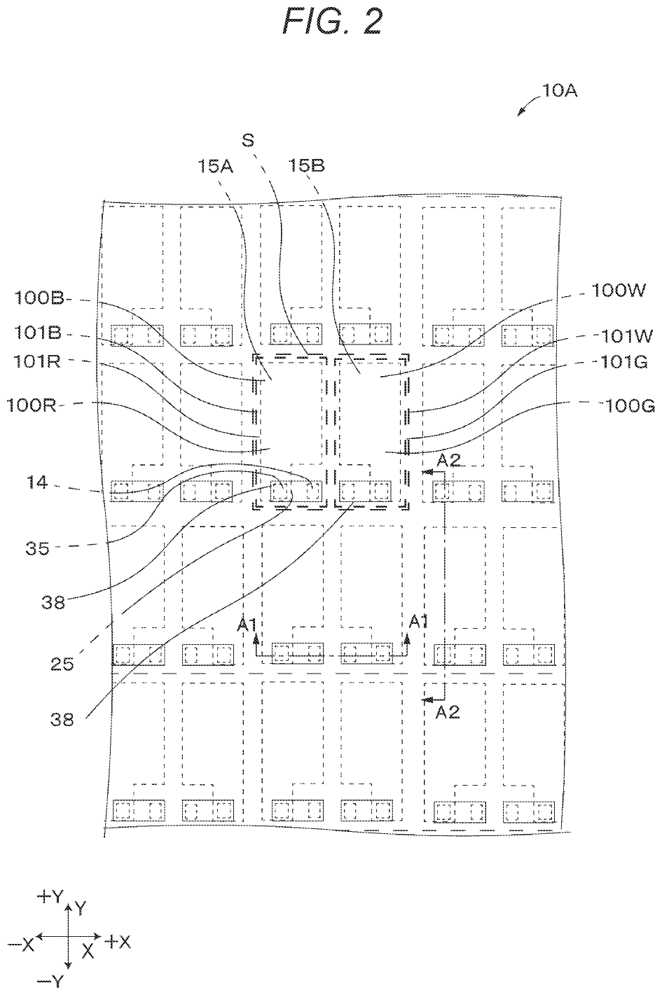

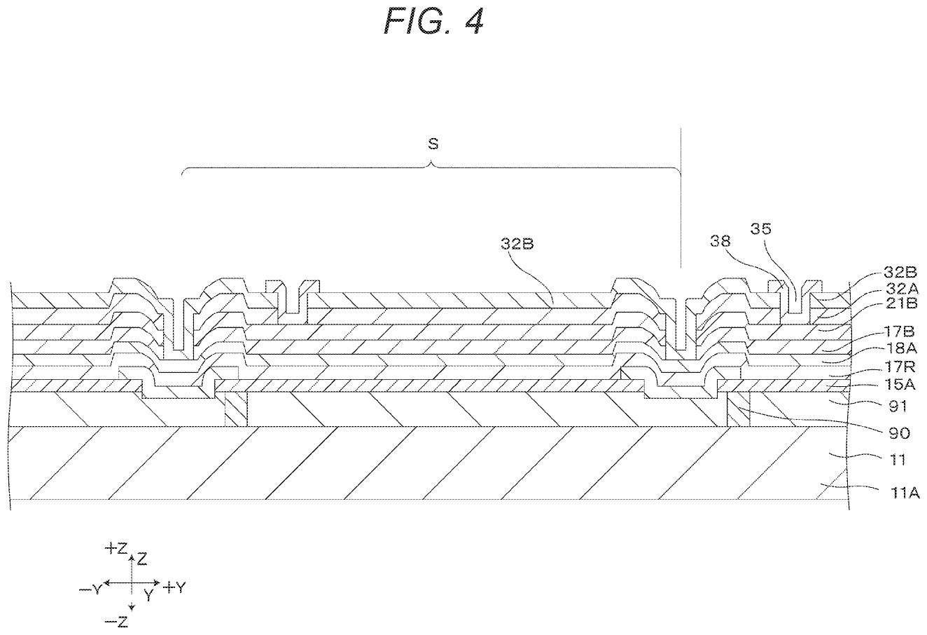

The following description is preferred specific examples of the present disclosure, and the content of the present disclosure is not limited to these embodiments and the like. Furthermore, in the following description, directions of front and back, left and right, up and down, and the like are indicated in consideration of convenience of description, but the content of the present disclosure is not limited to these directions. In examples of FIGS. 1, 2, and 3, it is assumed that the Z-axis direction is the up-down direction (upper side is in a +Z direction, and lower side is in a −Z direction), the X-axis direction is the front-back direction (front side is in a +X direction, and back side is in a −X direction), and the Y-axis direction is the left-right direction (right side is in a +Y direction, and left side is in a −Y direction), and the description will be made on the basis of this. This similarly applies to FIGS. 4 to 32. A relative magnitude ratio of the size and thickness of each layer illustrated in each drawing of FIG. 1 and the like is described for convenience, and do not limit actual magnitude ratios. This similarly applies to each drawing of FIGS. 2 to 35 regarding the definition and the magnitude ratio regarding these directions.

The light emitting device of the present disclosure may be used as, for example, a display device, or may be provided in the display device. Hereinafter, a case where the light emitting device is a display device, particularly a case where the light emitting device is a display device including a light emitting element having an organic EL layer will be described as an example. Note that the organic EL layer is an organic electroluminescent layer.

### 1 First Embodiment

### [1-1 Configuration of Display Device]

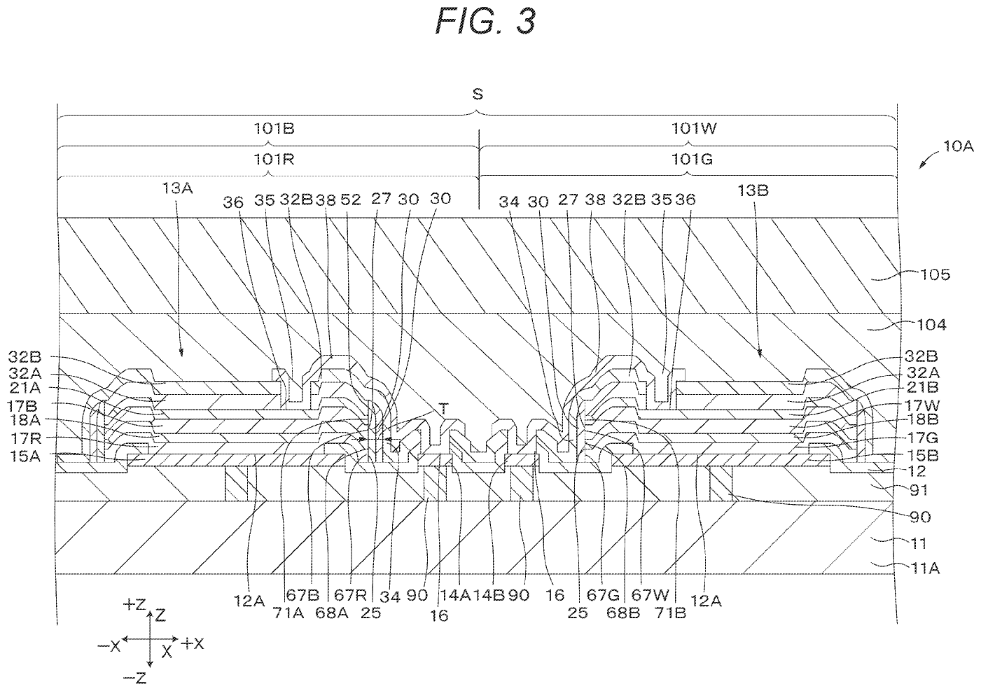

A display device according to a first embodiment will be described in detail with reference to FIGS. 2, 3, 4, and the like. A display device 10A has a laminated structure in which an organic EL element including an organic EL layer as an organic layer is formed vertically. In the example of FIG. 3, the display device 10A according to the first embodiment includes a plurality of laminated structures 13A and a plurality of laminated structures 13B. FIG. 3 is a cross-sectional view illustrating a configuration example of the display device 10A, which is an example according to the first embodiment of the present disclosure, and is a diagram illustrating a state of a longitudinal cross section taken along line A1-A1 in FIG. 2. Furthermore, FIG. 3 illustrates a portion of one pixel in the display device 10A. Note that FIG. 2 is a plan view illustrating an example of a pixel array of the display device according to the first embodiment. FIG. 4 is a cross-sectional view illustrating a state of a longitudinal cross section taken along line A2-A2 in FIG. 2.

The laminated structure 13A includes a first electrode 15A, an organic EL layer 17R as a first organic layer, a second electrode 18A, an organic EL layer 17B as a second organic layer, and a third electrode 21A.

The laminated structure 13B includes a first electrode 15B, an organic EL layer 17G as a first organic layer, a second electrode 18B, an organic EL layer 17W as a second organic layer, and a third electrode 21B.

Note that, hereinafter, in the present disclosure, in a case where the types of the organic EL layers such as the organic EL layer 17R, the organic EL layer 17B, the organic EL layer 17G, and the organic EL layer 17W are not particularly distinguished, the organic EL layer 17R, the organic EL layer 17B, the organic EL layer 17G, and the organic EL layer 17W may be collectively referred to as the organic EL layer 17.

In the following description, a case where the display device 10A is a top emission type display device will be described as an example. In the display device 10A, a drive substrate 11 is located on the back surface side of the display device 10A, and the direction from the drive substrate 11 toward the organic EL layer 17 (+Z direction) is the front surface side of the display device 10A (formation surface side of the display region PA). In the following description, in each layer constituting the display device 10A, a surface on the display region PA side of the display device 10A is referred to as a first surface (upper surface), and a surface on the back surface side of the display device 10A is referred to as a second surface (lower surface). A light emitting region is formed in a predetermined region on the display region PA side. In the display device, display is performed using the light emitting region as a display region. The method of the display device 10A and the determination of the first surface and the second surface are similar for the description of the second embodiment, the third embodiment, and the manufacturing method to be described later.

### (Organic EL Element)

In the laminated structure 13A, a plurality of organic EL elements 100 is formed side by side vertically. In addition, in the example of FIG. 3, also in the laminated structure 13B, a plurality of organic EL elements 100 is formed side by side in the vertical direction. In the laminated structure 13A, a combination of the first electrode 15A, the organic EL layer 17R, and the second electrode 18A forms an organic EL element 100R, and a combination of the second electrode 18A, the organic EL layer 17B, and the third electrode 21A forms an organic EL element 100B. In the laminated structure 13B, a combination of the first electrode 15B, the organic EL layer 17G, and the second electrode 18B forms an organic EL element 100G, and a combination of the second electrode 18B, the organic EL layer 17W, and the third electrode forms an organic EL element 100W.

### (Configuration of Pixel)

In the example of the display device 10A illustrated in FIG. 3, one pixel is formed by a combination of a plurality of subpixels corresponding to a plurality of color types. In this example, three colors of red, blue, and green are defined as a plurality of color types, and white is also defined. As the subpixels, there are provided four types of subpixels: a subpixel 101R, a subpixel 101G, a subpixel 101B, and a subpixel 101W. The subpixel 101R, the subpixel 101G, and the subpixel 101B are a red subpixel, a blue subpixel, and a green subpixel, respectively, and display red, blue, and green, respectively. The subpixel 101W is a white subpixel, and improves luminance. In the example of the display device 10A illustrated in FIG. 3 and the like, the organic EL element 100R, the organic EL element 100G, the organic EL element 100B, and the organic EL element 100W are formed in correspondence with the subpixel 101R, the subpixel 101G, the subpixel 101B, and the subpixel 101W. However, the example of FIG. 3 or the like is an example, and the display device 10A is not limited to a case of including a plurality of subpixels corresponding to a plurality of color types. One color type may be used. In addition, light (red light, green light, and blue light, respectively) corresponding to each color type of red, green, and blue can be defined as light having a dominant wavelength in a range of 610 nm to 650 nm, a range of 510 nm to 590 nm, and a wavelength range of 440 nm to 480 nm, respectively, for example.

In the display device 10A, the layout of the laminated structure 13A and the laminated structure 13B is determined in the display region PA as illustrated in FIG. 1 corresponding to the layout of pixels S. For example, as illustrated in the example of FIG. 2, the layout of the laminated structure 13A and the laminated structure 13B is a layout in which a combination of the laminated structure 13A and the laminated structure 13B is two-dimensionally arranged in two directions (the X-axis direction and the Y-axis direction in FIG. 2). FIG. 2 is a diagram for explaining a layout of pixels S in a region XS indicated by a broken line, and is a plan view for explaining an example of a display region PA. In FIG. 1, reference numeral PS denotes a non-display unit surrounding the display region PA.

Furthermore, the position of each subpixel 101 in the pixel S is appropriately determined. In the example of FIG. 2, the subpixel 101R and the subpixel 101B are arranged to overlap each other in a plan view of the display device 10A. In addition, the organic EL element 100G and the organic EL element 100W overlap each other in plan view of the display device 10A.

Note that, in a case where the subpixels 101R, 101G, 101B, and 101W are not particularly distinguished, the term “subpixel 101” is used. Furthermore, in a case where the organic EL elements 100R, 100G, 100B, and 100W are not particularly distinguished, the term “organic EL element 100” is used. Furthermore, regarding the drawings, in the example of FIG. 3, a portion of one pixel is extracted and illustrated, but in a case where there is a plurality of pixels, the configuration illustrated in FIG. 3 can be adopted for each pixel.

### (Drive Substrate)

In the drive substrate 11, various circuits for driving the plurality of organic EL elements 100 are provided on a substrate 11A. Examples of the various circuits include a drive circuit that controls driving of the organic EL element 100 and a power supply circuit that supplies power to the plurality of organic EL elements 100 (none of which are illustrated).

The substrate 11A may include, for example, glass or resin having low moisture and oxygen permeability, or may include a semiconductor in which a transistor or the like is easily formed. Specifically, the substrate 11A may be a glass substrate, a semiconductor substrate, a resin substrate, or the like. The glass substrate includes, for example, high strain point glass, soda glass, borosilicate glass, forsterite, lead glass, quartz glass, or the like. The semiconductor substrate includes, for example, amorphous silicon, polycrystalline silicon, monocrystalline silicon, or the like. The resin substrate includes, for example, at least one selected from a group including polymethyl methacrylate, polyvinyl alcohol, polyvinyl phenol, polyethersulfone, polyimide, polycarbonate, polyethylene terephthalate, polyethylene naphthalate, or the like.

An interlayer film 91 is formed on the first surface of the drive substrate 11, and a plurality of contact plugs 90 for electrically connecting the organic EL element 100 to various circuits provided on the substrate 11A is provided. The contact plug 90 is provided below a first electrode 15 to be described later and below a pad 14 (14A and 14B) to be described later.

### (First Electrode)

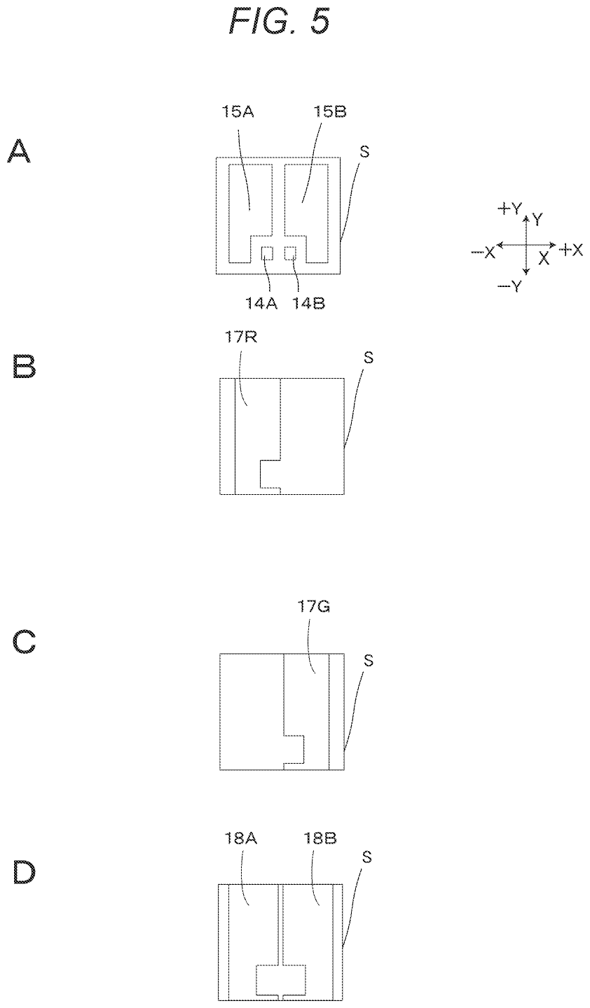

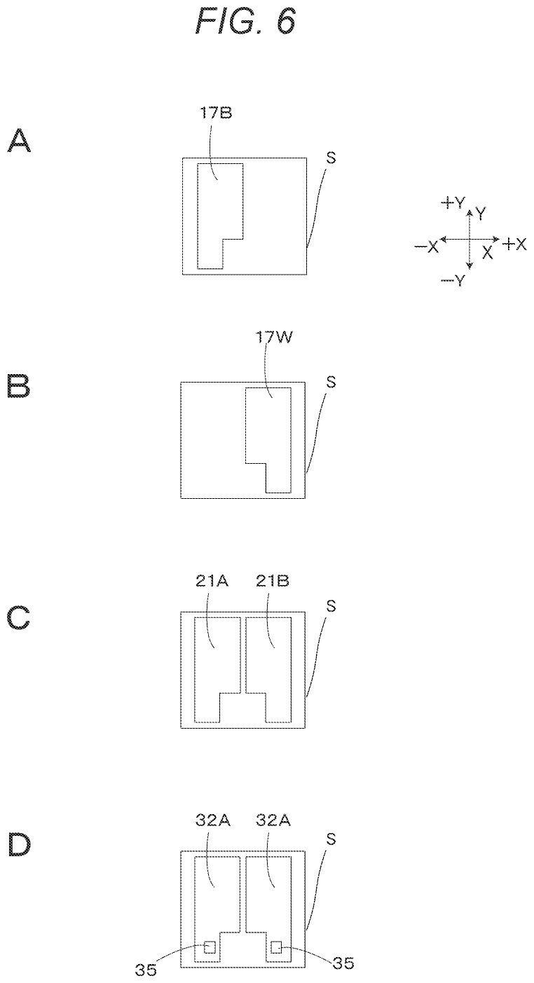

A plurality of first electrodes 15A and a plurality of first electrodes 15B are provided on the first surface side of the drive substrate 11. The plurality of first electrodes 15A is two-dimensionally arranged corresponding to the layout of the laminated structure 13A. The plurality of first electrodes 15B is two-dimensionally arranged corresponding to the layout of the laminated structure 13B. In the display device 10A of FIG. 3, as illustrated in FIG. 5A, the first electrode 15A and the first electrode 15B are arranged side by side in the X direction, avoiding the positions of the pads 14A and 14B, in a predetermined region in the section of the pixel S. FIG. 5A is a schematic plan view illustrating an arrangement region of the first electrode 15 and the pad 14 in the pixel S. It similarly applies to FIGS. 5B to 5D and FIGS. 6A to 6D.

In the example of FIG. 3, the first electrode 15A is an anode. When a voltage is applied to the first electrode 15A and the second electrode 18A, holes are injected from the first electrode 15A into the organic EL layer 17R. The first electrode 15B also serves as an anode, and when a voltage is applied to the first electrode 15A and the second electrode 18A, holes are injected from the first electrode 15A into the organic EL layer 17B.

Note that, hereinafter, in a case where the first electrode 15A and the first electrode 15B are not distinguished from each other, the first electrode 15A and the first electrode 15B may be collectively referred to as a first electrode 15.

From the viewpoint of improving the light extraction efficiency of the light emitted from the organic EL element 100, the first electrode 15 is preferably constituted by a material having high reflectance. Specifically, silver (Ag), aluminum (Al), an alloy thereof, or the like can be suitably used as the material of the first electrode 15. However, this does not prohibit the first electrode 15 from using a transparent electrode. For example, the first electrode 15 may have a laminated structure (for example, a laminated structure of ITO and Al) of a reflective electrode and a transparent electrode constituted by a material having high reflectivity. The transparent electrode is not particularly limited, and includes, for example, a transparent conductive oxide (TCO). Examples of the transparent conductive oxide include indium-based transparent conductive oxide, tin-based transparent conductive oxide, and zinc-based transparent conductive oxide. The transparent electrode may contain a plurality of kinds of the various kinds of transparent conductive oxides exemplified above.

The indium-based transparent conductive oxide indicates a transparent conductive oxide containing indium, and examples thereof include a group of compounds such as indium tin oxide (ITO), indium zinc oxide (IZO), and indium gallium oxide (IFO). The tin-based transparent conductive oxide indicates a tin-containing transparent conductive oxide, and examples thereof include a group of compounds such as tin oxide, antimony-doped tin oxide (ATO), and fluorine-doped tin oxide (FTO). The zinc-based transparent conductive oxide indicates a transparent conductive oxide containing zinc, and examples thereof include a group of compounds such as zinc oxide, aluminum-doped zinc oxide (AZO), and boron-doped zinc oxide. From the viewpoint of reducing the drive voltage of the display device 10A, it is preferable to use an electrode constituted by ITO as the transparent electrode for the first electrode 15.

### (Pad)

The pads 14A and 14B constituted by a conductive material are provided between the adjacent first electrodes 15. The pads 14A and 14B are connected to the contact plug 90. In addition, the pads 14A and 14B are electrically connected to the third electrodes 21A and 21B, respectively. In a case where the pads 14A and 14B are not distinguished from each other, the pads 14A and 14B are hereinafter collectively referred to as a pad 14.

### (Insulating Layer)

An insulating layer 12 having an opening 12A is formed between the adjacent first electrodes 15. The insulating layer 12 is formed on the surface of the interlayer film 91 described later and the first surface of the first electrode 15. The opening 12A of the insulating layer 12 is formed at a position where the first electrode 15 is formed in plan view of the display device 10A. Note that the plan view of the display device 10A indicates a case where the up-down direction (Z-axis direction) is the line-of-sight direction. The opening 12A is formed in a pattern according to the arrangement pattern of the subpixels 101, and one section of the opening 12A defines a unit section of the subpixel 101.

In the example of FIG. 3, a unit section of the subpixel 101B is defined in the opening 12A formed immediately below the first electrode 15A. In the opening 12A formed immediately below the first electrode 15B, a unit section of the subpixel 101G is defined.

As illustrated in the example of FIG. 3, the opening 12A is provided on the first surface of the first electrode 15. The fact that the opening 12A is formed on the first surface of the first electrode 15 indicates that the insulating layer 12 is formed so as to cover the side end surface of the first electrode 15 and the outer edge portion of the upper surface (first surface) and to ride on the upper surface side of the first electrode 15. The insulating layer 12 is a layer that electrically separates the adjacent first electrodes 15. The insulating layer 12 is not particularly limited, and may be constituted by an organic insulating film such as a polyimide-based resin or an inorganic insulating film such as silicon nitride.

In addition, the insulating layer 12 is also opened at a position on the upper surface side of the pad 14 so that the upper surface side of the pad 14 provided between the adjacent first electrodes 15 is exposed, and this opened portion is a connection hole 16 for the pad 14.

### (Organic EL Layer)

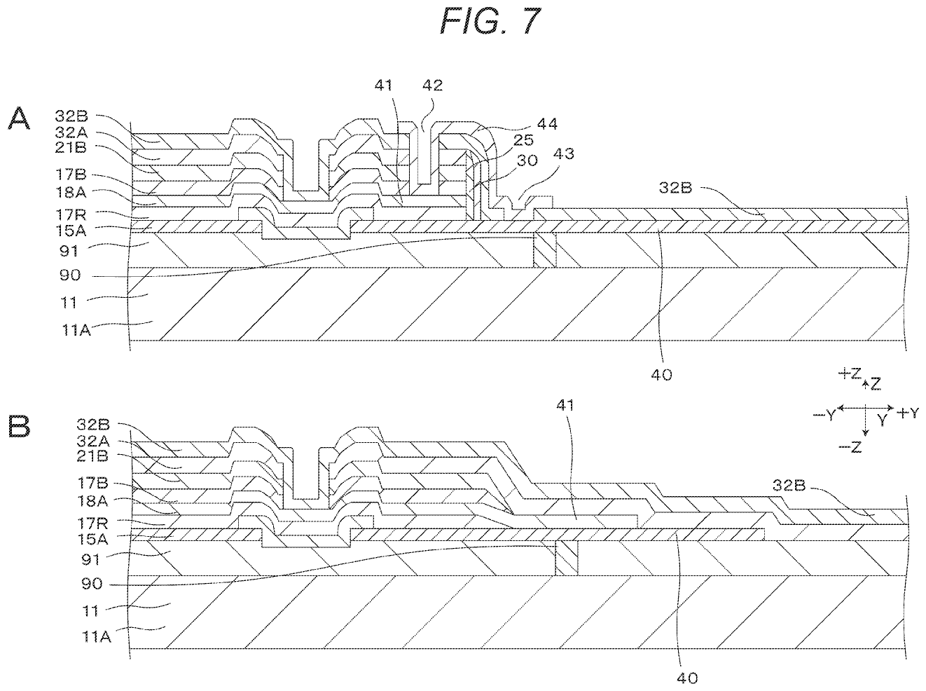

As illustrated in FIG. 3, the organic EL layer 17R is disposed between the first electrode 15A and the second electrode 18A described later. The organic EL layer 17R covers the first electrode 15A and the insulating layer 12. In the example of FIG. 3, in plan view of the display device 10A, the organic EL layer 17R is formed in a range corresponding to the subpixel 101R. In addition, since the organic EL layer 17R is formed in a stripe shape extending in the Y-axis direction without being separated between the adjacent pixels S as illustrated in FIG. 4, the organic EL layer is formed in a shape extending from one end to the other end of the pixel S along the Y-axis direction in the pixel S as illustrated in FIG. 5B. Note that, in FIG. 4, for convenience of description, a filling resin layer 104 and a counter substrate 105, which will be described later, are omitted. It similarly applies to FIGS. 7A, 7B, 8, 9, 10, 11, 13, 14, 19, and the like.

The organic EL layer 17R includes at least a light emitting layer. The light emitting layer is constituted by an organic light emitting material. In the light emitting layer, coupling between holes injected from each of the first electrode 15A and the second electrode 18A and electrons occurs, and light is generated. The generated light becomes emission light from the organic EL layer 17. The emission light from the organic EL layer 17R is light having red as a dominant wavelength component.

The organic EL layer 17R may have a structure in which a hole transport layer, a light emitting layer, and an electron transport layer are laminated in this order from the first electrode 15A toward the second electrode 18A (from bottom to top). When the organic EL layer 17R has such a structure, the light emission efficiency can be further increased. Furthermore, the organic EL layer 17R may have a structure in which a hole injection layer, a hole transport layer, a light emitting layer electron, an injection layer, and an electron transport layer are laminated in this order from the first electrode 15A toward the second electrode 18A.

In addition, the organic EL layer 17G is disposed between the first electrode 15B and a second electrode 18B described later. The organic EL layer 17G covers the first electrode 15B and the insulating layer 12. The organic EL layer 17G is formed in a range corresponding to the subpixel 101G. The organic EL layer 17G may adopt a layer structure similar to that of the organic EL layer 17R except that light having green as a dominant wavelength component is used as emission light. Similarly to the organic EL layer 17R, since the organic EL layer 17G is formed in a stripe shape extending along the Y-axis direction without being separated between the adjacent pixels S as illustrated in FIG. 4, the organic EL layer 17G is formed in a shape extending from one end to the other end of the pixel S along the Y-axis direction in the pixel S as illustrated in FIG. 5C.

As illustrated in FIG. 3, the organic EL layer 17B is disposed between the third electrode 21A to be described later and the second electrode 18A to be described later. The organic EL layer 17B covers the upper surface side of the second electrode 18A. In the example of the display device 10A of FIG. 3, the organic EL layer 17B is formed in a range corresponding to the subpixel 101B. The organic EL layer 17B may adopt a layer structure similar to that of the organic EL layer 17R except that light having blue as a dominant wavelength component is used as emission light. Since the shape of the organic EL layer 17B is separated between the adjacent pixels S as illustrated in FIG. 4, the organic EL layer is formed in a region inside the pixel S in the pixel S as illustrated in FIG. 6A.

The organic EL layer 17W is disposed between the third electrode 21B described later and the second electrode 18B described later. The organic EL layer 17W covers the upper surface side of the second electrode 18B. The organic EL layer 17W is formed in a range corresponding to the subpixel 101W. The organic EL layer 17W may adopt a layer structure similar to that of the organic EL layer 17R except that white light is used as emission light. Since the shape of the organic EL layer 17W is separated between the adjacent pixels S as illustrated in FIG. 4, the organic EL layer is formed in a region inside the pixel S in the pixel S as illustrated in FIG. 6B.

### (Second Electrode)

In the display device 10A, each of the plurality of second electrodes 18A is disposed on the first surface side of the first electrode 15A. The second electrode 18A is a common electrode corresponding to the first electrode 15A and the third electrode 21A. In addition, the plurality of second electrodes 18A is arranged on the first surface side of the first electrode 15B. The second electrode 18B is a common electrode corresponding to the first electrode 15B and the third electrode 21B. In the example of the display device 10A in FIG. 3, the second electrode 18A is an electrode of the subpixels 101R and 101B, and the second electrode 18B is an electrode of the subpixels 101G and 101W.

Since both the second electrode 18A and the second electrode 18B are formed in a stripe shape extending in the Y direction without being separated between the adjacent pixels S as illustrated in FIG. 4, the second electrode is formed in a shape extending from one end to the other end of the pixel S along the Y direction in the pixel S as illustrated in FIG. 5D.

Note that, hereinafter, in a case where the second electrode 18A and the second electrode 18B are not distinguished from each other, the second electrode 18A and the second electrode 18B may be collectively referred to as a second electrode 18.

In the example of FIG. 3, the second electrode 18 (the second electrode 18A and the second electrode 18B) is a cathode. When a voltage is applied to the first electrode 15A and the second electrode 18A, electrons are injected from the second electrode 18A into the organic EL layer 17R. When a voltage is applied to the third electrode and the second electrode, electrons are injected from the second electrode 18A into the organic EL layer 17B. In addition, when a voltage is applied to the first electrode 15B and the second electrode 18B, electrons are injected from the second electrode 18B into the organic EL layer 17G. When a voltage is applied to the third electrode and the second electrode, electrons are injected from the second electrode 18B into the organic EL layer 17W.

The second electrode 18 has a property of allowing emission light generated from the organic EL layer 17 to pass therethrough. In addition, the second electrode 18 is preferably capable of semi-transmitting the emission light generated from the organic EL layer 17. For example, from this viewpoint, a semi-transmissive electrode may be used as the second electrode 18 in addition to a transparent electrode. Note that the semi-transmissive electrode is an electrode having both a property of reflecting light and a property of transmitting light. From the viewpoint of improving the light emission efficiency of the organic EL element 100, the second electrode 18 is preferably constituted by a layer having a low work function.

The second electrode 18 may be constituted by, for example, a single-layer film or a multilayer film of one of the metal layer and the metal oxide layer, or may be constituted by a laminated film of the metal layer and the metal oxide layer. In a case where the second electrode 18 is constituted by a laminated film of a metal layer and a metal oxide layer, the metal layer is preferably directed to the organic EL layer 17 from the viewpoint of making a layer having a low work function face the organic EL layer. As the metal layer, for example, it is preferable to contain at least one metal element selected from the metal group consisting of magnesium (Mg), aluminum (Al), silver (Ag), calcium (Ca), sodium (Na), or the like. The metal layer may be an alloy containing a metal element selected from the above metal group as a constituent element. Examples of the metal oxide include ITO, IZO, and ZnO.

### (Third Electrode)

In the display device 10A, each of the plurality of third electrodes 21A is disposed on the first surface side of the organic EL layer 17B. In addition, each of the plurality of third electrodes 21B is arranged on the first surface side of the organic EL layer 17W. Since the shapes of the third electrodes 21A and 21B are separated between the adjacent pixels S as illustrated in FIG. 4, the third electrodes are formed in the inner region of the pixel S as illustrated in FIG. 6C.

Note that, hereinafter, in a case where the third electrode 21A and the third electrode 21B are not distinguished from each other, the third electrode 21A and the third electrode 21B may be collectively referred to as a third electrode 21.

In the example of FIG. 3, the third electrode 21A is an anode. When a voltage is applied to the third electrode 21A and the second electrode 18A, holes are injected from the third electrode 21A into the organic EL layer 17B. The third electrode 21B also serves as an anode, and when a voltage is applied to the third electrode 21B and the second electrode 18B, holes are injected from the third electrode 21B into the organic EL layer 17W.

The third electrode 21 may be constituted by a material similar to the material that can be adopted as the first electrode 15 as long as it has a property of passing the emission light generated from the organic EL layer 17. Specifically, the third electrode 21 may be constituted by ITO, IZO, or the like.

In the example of the display device 10A illustrated in FIG. 3, the first electrode 15 and the third electrode 21 are electrically separated from each other. In this case, the first electrode 15 and the third electrode 21 are individually controlled, and the voltage application to the organic EL layer 17R and the voltage application to the organic EL layer 17B are individually controlled. In addition, the voltage application to the organic EL layer 17G and the voltage application to the organic EL layer 17W are individually controlled.

### (Wall Surface Portion)

A wall surface portion 25 is formed in at least a part of the laminated structures 13A and 13B. The wall surface portion 25 in the laminated structure 13A is defined as a portion having, at least in part, a connecting surface 27 in which a sidewall 67R of the organic EL layer 17R, a sidewall 68A of the second electrode 18A, and a sidewall 67B of the organic EL layer 17B are connected. In the example of FIG. 3, at least both wall surfaces (side end surfaces) of the laminated structures 13A and 13B facing each other across the pad 14 in the region of the pixel S form the wall surface portion 25.

As illustrated in FIG. 3, the wall surface portion 25 is in a state where the positions of the sidewall 67R, the sidewall 68A, and the sidewall 67B are aligned in the up-down direction in the portion of the connecting surface 27. Therefore, by forming the wall surface portion 25 having the connecting surface 27, a portion that is not used for light emission as the organic EL element 100 in the organic EL layer 17 and the second electrode 18 can be reduced, and the aperture ratio of the display device 10A can be easily improved. From this viewpoint, on the connecting surface 27 of the wall surface portion 25, the sidewall 67R, the sidewall 68A, and the sidewall 67B are preferably aligned flush with each other. In addition, the connecting surface 27 of the wall surface portion 25 is preferably formed in a state in which a sidewall 71A of the third electrode 21A is further connected. In the example of the connecting surface 27 of the wall surface portion 25 illustrated in FIG. 3, the sidewall 67R, the sidewall 68A, the sidewall 67B, and the sidewall 71A are aligned in order from the lower side to the upper side. In the example of FIG. 3, the sidewall 67R, the sidewall 68A, the sidewall 67B, and the sidewall 71A are arranged to be flush with each other.

The wall surface portion 25 of the laminated structure 13B has, at least in a part, the connecting surface 27 in which a sidewall 67G of the organic EL layer 17G, a sidewall 68B of the second electrode 18B, and a sidewall 67W of the organic EL layer 17W are connected. Also in the laminated structure 13B, similarly to the laminated structure 13A, the sidewall 67G, the sidewall 68B, and the sidewall 67W are preferably arranged to be flush with each other. The connecting surface 27 of the wall surface portion 25 is preferably formed in a state in which a sidewall 71B of the third electrode 21B is further connected. In the example of the connecting surface 27 of the wall surface portion 25 illustrated in FIG. 3, the sidewall 67G, the sidewall 68B, the sidewall 67W, and the sidewall 71B are aligned in order from the lower side to the upper side. In the example of FIG. 3, the sidewall 67G, the sidewall 68B, the sidewall 67W, and the sidewall 71B are aligned flush with each other.

### (Sidewall Insulating Layer)

In the display device 10A, a sidewall insulating layer 30 is provided on the outer surface of the wall surface portion 25. The sidewall insulating layer 30 formed in the laminated structure 13A covers the sidewall 67R, the sidewall 68A, and the sidewall 67B forming the connecting surface 27 on the outer surface of the wall surface portion 25, thereby restricting the organic EL layer 17R, the second electrode 18A, and the organic EL layer 17B from being exposed to the external environment. The sidewall insulating layer 30 formed in the laminated structure 13B covers the sidewall 67G, the sidewall 68B, and the sidewall 67W, and restricts exposure of the organic EL layer 17G, the second electrode 18B, and the organic EL layer 17W to an external environment. Note that the sidewall insulating layer 30 may be formed so as to cover the sidewall 71A of the third electrode 21A and the sidewall 71B of the third electrode 21B.

The sidewall insulating layer 30 may have a single layer structure or a multilayer structure. The wall surface portion 25 of the laminated structure 13A has a multilayer structure in which two sidewall insulating layers 30 and 30 are formed. The sidewall insulating layer 30 is formed as a single layer on the wall surface portion 25 of the laminated structure 13B.

The sidewall insulating layer 30 is constituted by an insulating material. Examples of the material of the sidewall insulating layer 30 include SiN, SiON, SiO, AlO, and TiO. The sidewall insulating layer 30 can be formed by processing a chemical vapor deposition (CVD) film, an atomic layer deposition (ALD) film, or the like using such a material so as to remain on the wall surface portion 25 by photolithography, etching, or the like, or by remaining on the wall surface portion 25 by a sidewall process. In addition, the sidewall insulating layer 30 may be, for example, a layer constituted by a processing byproduct including a byproduct (deposition) generated by etching processing. The etching processing in this case indicates processing by an etching method in the batch formation process described in the description of the manufacturing method of the display device 10A to be described later. The etching processing is preferably a dry etching method from the viewpoint of accurately processing the wall surface portion 25 to be the same plane.

As the sidewall insulating layer 30, a layer of SiN, SiON, SiO, AlO, or TiO formed by the CVD method, the ALD method, or the like as described above is suitably used. Note that, in a case where a gas having a relatively high carbon ratio such as C₄F₈ is used as an etching gas at the time of etching processing, an organic material or the like (specifically, a hydrocarbon containing a fluorine atom or the like) may be contained in the sidewall insulating layer 30. In this case, C is contained as an element in the sidewall insulating layer 30. For these reasons, the sidewall insulating layer 30 preferably contains at least one element selected from the element group consisting of Si, N, O, Al, Ti, or C.

The average thickness of the sidewall insulating layer 30 is not particularly limited, but is preferably 5 nm or more and 1 μm or less, and more preferably 5 nm or more and 300 μm or less. Note that the thickness of the sidewall insulating layer 30 indicates a thickness T (in FIG. 3, reference numeral T is used) along a direction perpendicular to the surface direction of the wall surface portion 25. In addition, in a case where the sidewall insulating layer 30 has a multilayer structure, the average thickness of the sidewall insulating layer 30 indicates the average thickness of the sidewall insulating layer 30 in the total thickness. For example, the sidewall insulating layer 30 formed in the laminated structure 13A indicates the thickness of the entire two stacked layers.

The average thickness of the sidewall insulating layer 30 can be determined, for example, as follows. A cross section of the display device 10A (a cross section parallel to the thickness direction of the display device 10A) is cut out by cryo-focused ion beam (FIB) processing or the like to prepare a thin piece. The prepared thin piece is observed with a transmission electrom microscope (TEM) to acquire a cross-sectional TEM image of the thin piece. The thickness T of the sidewall insulating layer 30 is measured at 10 or more measurement positions in the acquired cross-sectional TEM image. The measurement positions are selected randomly. An average value (arithmetic average value) of the measured thicknesses T of the sidewall insulating layer 30 at 10 or more points is calculated. This arithmetic average value is determined as the average thickness of the sidewall insulating layer 30.

### (Protective Layer)

Protective layers 32A and 32B are formed on the third electrode 21. The protective layer 32A is provided so as to cover the third electrode 21, and the protective layer 32B is provided so as to further cover the protective layer 32A. Both the protective layer 32A and the protective layer 32B are constituted by an insulating material. As the insulating material, SiO, SiON, SiN, AlO, TiO, or the like may be used. In this case, as the protective layer 32A and the protective layer 32B, a CVD film containing SiO, SiON, SiN, or the like, an ALD film containing AlO, TiO, SiO, or the like, or the like can be exemplified. In addition, as the insulating material, for example, a thermosetting resin or the like can be used.

In the example of FIG. 3, the protective layer 32A covers the upper surface of the third electrode 21, and the sidewall 52 of the protective layer 32A is covered with the sidewall insulating layer 30. Since the protective layer 32A is separated between adjacent pixels S as illustrated in FIG. 4, the protective layer is formed in an inner region of the pixel S as illustrated in FIG. 6D.

In addition, the protective layer 32B covers the upper surface side of the protective layer 32B and further covers the outer surface of the sidewall insulating layer 30. As illustrated in FIG. 4, the protective layer 32B is continuous in the Y-axis direction, and is a layer common to the pixels arranged in the Y-axis direction.

### (Insulating Auxiliary Portion)

As illustrated in FIG. 3, the protective layer 32B covers the sidewall insulating layer 30. A portion of the protective layer 32B covering the sidewall insulating layer 30 is an insulating auxiliary portion 34. The insulating auxiliary portion 34 reinforces insulation by the sidewall insulating layer 30.

Note that, in the example of FIG. 3, two layers of the protective layers 32A and 32B are formed, but three or more layers may be formed as the protective layer, or a single layer may be formed.

### (Connection Hole)

A connection hole 35 penetrating the protective layers 32A and 32B is formed at a predetermined position in the protective layers 32A and 32B. An upper surface 36 side of the third electrode 21 is exposed from the connection hole 35. The formation of the connection hole 35 in the protective layers 32A and 32B can be realized by appropriately using a method such as an etching method.

### (Wiring)

In the display device 10A, a wiring 38 is provided as an electrode relay portion on the upper surface side of the protective layer 32B. The wiring 38 extends from the third electrode 21 toward the drive substrate 11 side (toward the substrate 11A side), and is electrically connected to the pad 14 of the drive substrate 11. That is, the wiring 38 is connected to the upper surface 36 side of the third electrode 21 in the connection hole 35. Then, the wiring 38 passes through the outer surface side of the wall surface portion 25 from the connection hole 35 and extends along the surface of the protective layer 32B toward the pad 14. Then, the sidewall insulating layer 30 is interposed between the wiring 38 and the wall surface portion 25. Note that the third electrode 21A is electrically connected to the pad 14A via the wiring 38, and the third electrode 21B is connected to the pad 14B via the wiring 38. As a result, the organic EL layer 17B and the organic EL layer 17W are individually controlled.

### (Filling Resin Layer)

In the display device 10A, the filling resin layer 104 may be formed so as to cover the protective layer 32B. The filling resin layer 104 can protect the wiring 38 and planarize the first surface side of the protective layer 32B. The filling resin layer 104 can have a function as an adhesive layer for bonding the protective layer 32B and the counter substrate 105 described later. Examples of the filling resin layer 104 include ultraviolet curable resin, thermosetting resin, and the like. Note that, although not illustrated, a protective layer may be formed by a CVD method, an ALD method, or the like in order to protect the exposed electrode before the filling resin layer 104 is formed.

### (Counter Substrate)

The counter substrate 105 is provided on the filling resin layer 104 in a state of facing the drive substrate 11. The counter substrate 105 seals the organic EL element 100 together with the filling resin layer 104. The counter substrate 105 is preferably constituted by a material such as glass. Note that a lens may be formed on the filling resin layer 104 (not illustrated). Furthermore, the lens may be formed before the filling resin layer 104 is formed. For example, before the filling resin layer 104 is formed, a planarizing layer may be constituted by resin or the like, and a lens may be formed on the planarizing layer.

### (Auxiliary Electrode)

In the display device 10A, as illustrated in FIGS. 7A and 7B, an auxiliary electrode 40 is preferably provided outside the light emitting region (outside the display region PA). The second electrode 18 is electrically connected to the auxiliary electrode 40. As illustrated in FIG. 4, the second electrode 18 is continuously formed in the Y-axis direction, and functions as a common electrode for pixels adjacent in the Y-axis direction. The second electrode 18 is not connected to the pad 14 in the display region PA of the drive substrate 11, and an end portion 41 on the longitudinal direction (Y-axis direction) side is formed up to the outside of the display region PA or the outer peripheral edge portion of the display region PA, and is electrically directly or indirectly connected to the auxiliary electrode 40.

The shape of the auxiliary electrode 40 is not particularly limited, but for example, may be formed in an annular shape so as to surround the outside of the display region PA. In this case, the second electrode 18 is preferably connected to the auxiliary electrode 40 at each of the end portions 41 on both sides on the longitudinal direction side.

Note that a connection structure between the second electrode 18 and the auxiliary electrode 40 is not particularly limited. For example, as a structure for indirectly connecting the second electrode 18 and the auxiliary electrode 40, a structure using a wiring 44 can be mentioned. In the example of FIG. 7A, a connection hole 42 is formed above the end portion 41 of the second electrode 18, and a connection hole 43 is also formed on the auxiliary electrode 40. The wiring 44 is connected to the end portion 41 of the second electrode 18 in the connection hole 42. The wiring 44 extends from the end portion 41 of the second electrode 18 to the auxiliary electrode 40, and is connected to the auxiliary electrode 40 in the connection hole 42. Consequently, the second electrode 18 and the auxiliary electrode 40 can be connected by the wiring 44. Note that, in this case, the wall surface portion 25 is preferably formed at the portion of the end portion 41 of the second electrode 18. In this case, the sidewall insulating layer 30 may be formed. The wiring 44 passes from the second electrode 18 to the outside of the sidewall insulating layer 30, extends to the auxiliary electrode 40, and connects the second electrode 18 and the sidewall insulating layer 30.

As a structure for directly connecting the second electrode 18 and the auxiliary electrode 40, for example, as illustrated in FIG. 7B, the second electrode 18 may be formed such that the end portion 41 of the second electrode 18 is extended to the position of the upper surface of the auxiliary electrode 40, and connected to the auxiliary electrode 40 at the end portion 41.

### [1-2 Operation and Effect]

In a case where the end portions of the first organic layer, the second electrode, and the second organic layer are formed to be shifted from each other, a portion where the first organic layer and the second electrode do not overlap each other or a portion where the second electrode and the second organic layer do not overlap each other is out of the pixel range. Therefore, a region required for providing one pixel is widened, and there is room for improvement in terms of increasing the ratio (aperture ratio) of the area that can be used as a pixel in the display region PA to achieve higher luminance.

According to the display device 10A according to the first embodiment, since the wall surface portion 25 in which the positions of the sidewalls 67R, 68A, and 67B of the organic EL layer 17R as the first organic layer, the second electrode 18A, and the organic EL layer 17B as the second organic layer are aligned is formed in the laminated structure 13A, and the wall surface portion 25 in which the positions of the sidewalls 67G, 68B, and 67W are aligned is formed in the laminated structure 13B, the distance between the laminated portion of the organic EL layer 17R, the second electrode 18A, and the organic EL layer 17B and the pad 14 and the distance between the laminated portion of the organic EL layer 17G, the second electrode 18B, and the organic EL layer 17W and the pad 14 can be further shortened, and the aperture ratio can be improved.

In addition, according to the display device 10A according to the first embodiment, since the sidewall insulating layer 30 is formed on the wall surface portion 25, even in a case where the wiring 38 serving as the electrode relay portion is connected from the third electrode 21 to the pad 14, the wiring 38 can be prevented from coming into contact with the second electrode 18 and the organic EL layer 17, and the occurrence of current leakage can be suppressed.

### [1-3 Modifications]

The display device according to the first embodiment is not limited to those described above, and may be formed, for example, as illustrated in the following modifications.

### [Modification 1]

### (Configuration)

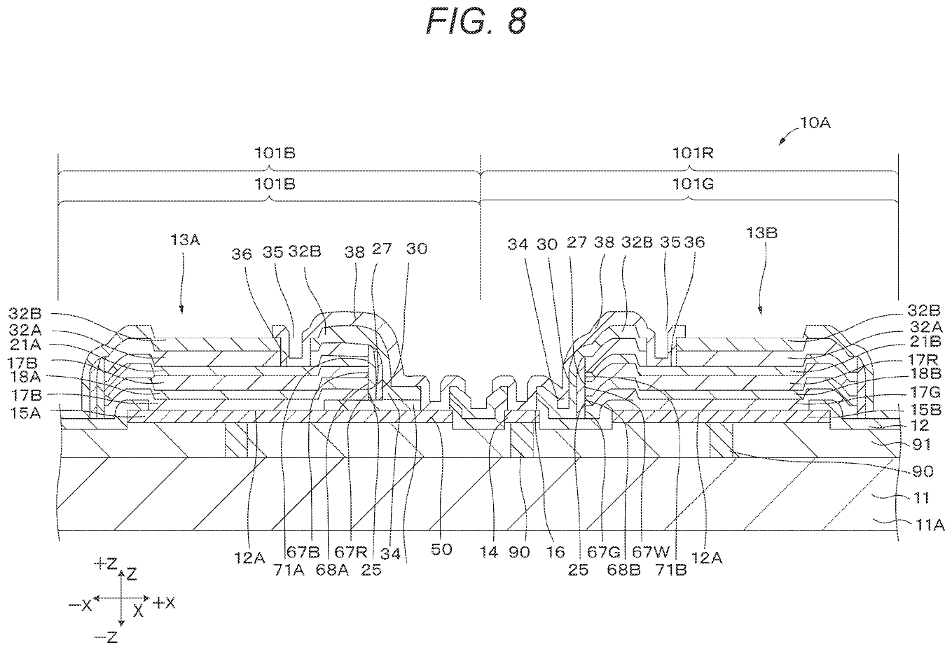

As illustrated in FIG. 8, a display device 10A according to the first embodiment may be the organic EL layer 17 in which a first organic layer disposed between the first electrode 15 and the second electrode 18 and a second organic layer disposed between the second electrode 18 and the third electrode 21 have emission light of the same color (Modification 1). In the example of FIG. 8, the organic EL layer 17B is used as both the first organic layer and the second organic layer formed in the laminated structure 13A, and a structure in which the organic EL elements 100B are stacked in two stages is formed. Furthermore, at this time, each organic EL element 100B corresponds to the subpixel 101B.

In Modification 1, the third electrode 21A formed in the laminated structure 13A is electrically connected to the first electrode 15A. In the example illustrated in FIG. 8, the first electrode 15A forms an extended end portion 50 extending outward from the organic EL layer 17B (the organic EL layer 17B disposed between the first electrode 15A and the second electrode 18A) in direct contact with the first electrode 15A. In addition, the wiring 38 is electrically connected to the upper surface 36 of the third electrode 21A at a position in the connection hole 35. The wiring 38 extends from the third electrode 21A along the surface of the protective layer 32B to the drive substrate 11 side through the outside (on the surface of the protective layer 32B) of the sidewall insulating layer 30 formed on the outer surface of the wall surface portion 25, and is electrically connected to the extended end portion 50 of the first electrode 15A.

In Modification 1, one pad 14 is provided between adjacent first electrodes 15 in one pixel. The wiring 38 connected to the third electrode 21B of the laminated structure 13B is electrically connected to the pad 14. In the display device illustrated in FIG. 8, in the laminated structure 13B, the organic EL layer 17G is provided below the second electrode 18B, and the organic EL layer 17R is provided above the second electrode 18B. Therefore, the laminated structure 13B forms a structure in which the organic EL element 100G and the organic EL element 100R overlap each other. Furthermore, a formation region of the organic EL element 100G and the organic EL element 100R forms the subpixels 101G and 101R. Therefore, in the display device of Modification 1, one pixel is formed by the subpixels 101 (subpixels 101R, 101G, and 101B) of three types of colors.

The display device 10A of Modification 1 may be similar to the display device described in the first embodiment except for the above.

### (Effect)

The display device 10A of Modification 1 can obtain similar effects to those of the display device described in the first embodiment.

### [Modification 2]

### (Configuration)

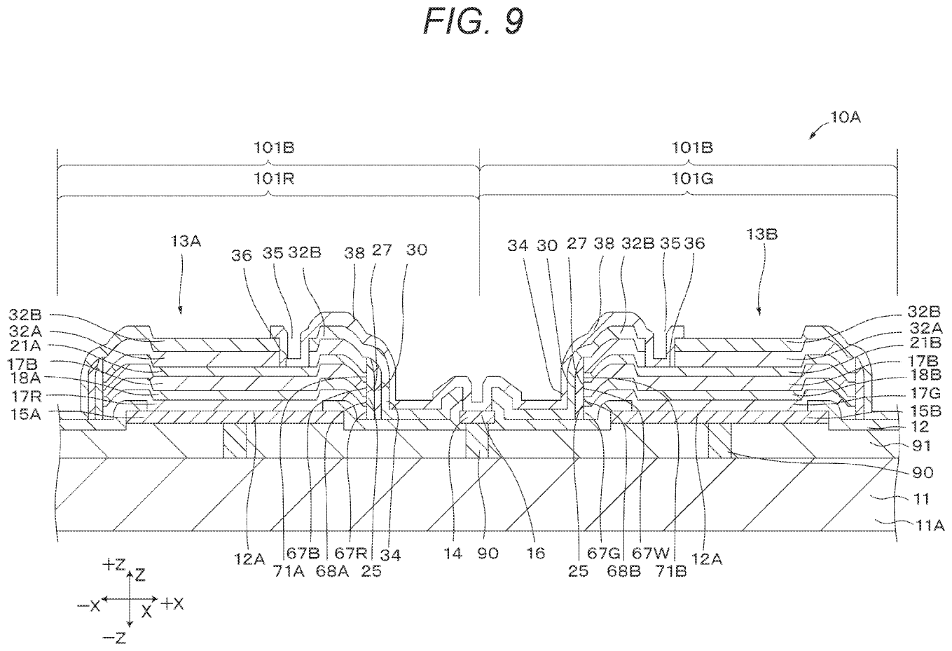

In the display device 10A according to the first embodiment, as illustrated in FIG. 9, the organic EL layer 17B may be disposed between the third electrode 21A and the second electrode 18A of the laminated structure 13A, and the organic EL layer 17B may also be disposed between the third electrode 21B and the second electrode 18B of the laminated structure 13B (Modification 2).

In an example of Modification 2 illustrated in FIG. 9, in the laminated structure 13B, a structure in which the organic EL element 100G and the organic EL element 100B overlap is formed.

In addition, in Modification 2, one pad 14 is provided between the adjacent first electrodes 15. As described above, both the wiring 38 directed from the upper surface 36 of the third electrode 21A of the laminated structure 13A toward the drive substrate 11 side and the wiring 38 directed from the third electrode 21B of the laminated structure 13B toward the drive substrate 11 side are electrically connected to the pad 14. As a result, it becomes easy to synchronize the light emission states of the organic EL layer 17B provided in the laminated structure 13A and the organic EL layer 17B provided in the laminated structure 13B. Note that, in the display device illustrated in FIG. 9, the organic EL layer 17R is disposed between the first electrode 15A and the second electrode 18A, and the organic EL layer 17G is disposed between the first electrode 15B and the second electrode 18B. Therefore, in the display device of Modification 2, one pixel is constituted by three types of subpixels (subpixels 101R, 101G, and 101B).

The display device 10A of Modification 2 may be similar to the display device 10A described in the first embodiment except for the above.

### (Effect)

The display device 10A of Modification 2 can obtain similar effects to those of the display device 10A described in the first embodiment.

### [Modification 3]

### (Configuration)

In the display device 10A of the first embodiment, each of the laminated structure 13A and the laminated structure 13B may form one pixel S (Modification 3). In this case, the combination of the color types of the organic EL layers 17 arranged in the laminated structure 13A is different from the combination of the color types of the organic EL layers 17 arranged in the second laminated structure.

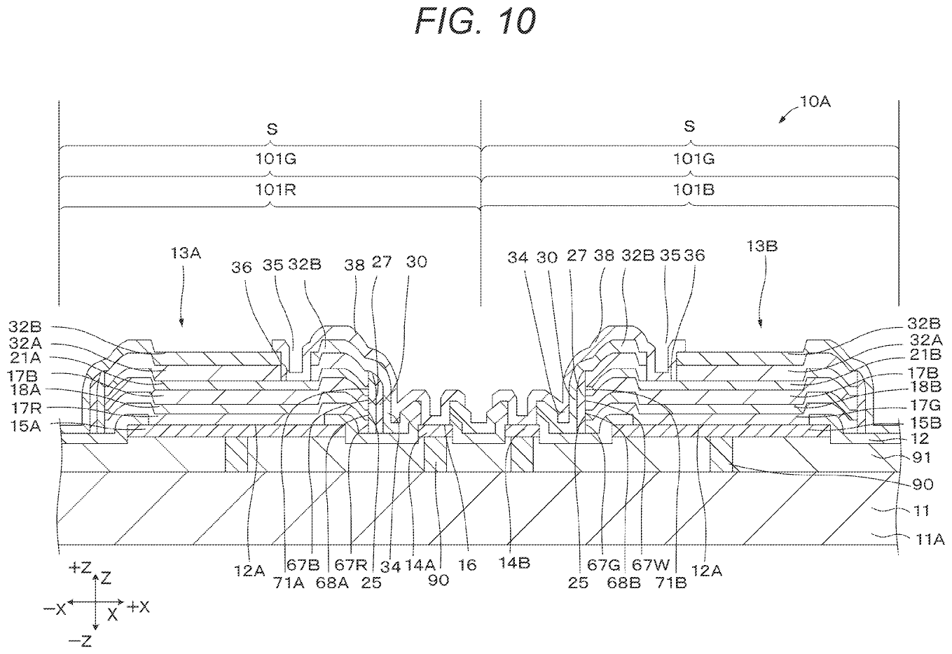

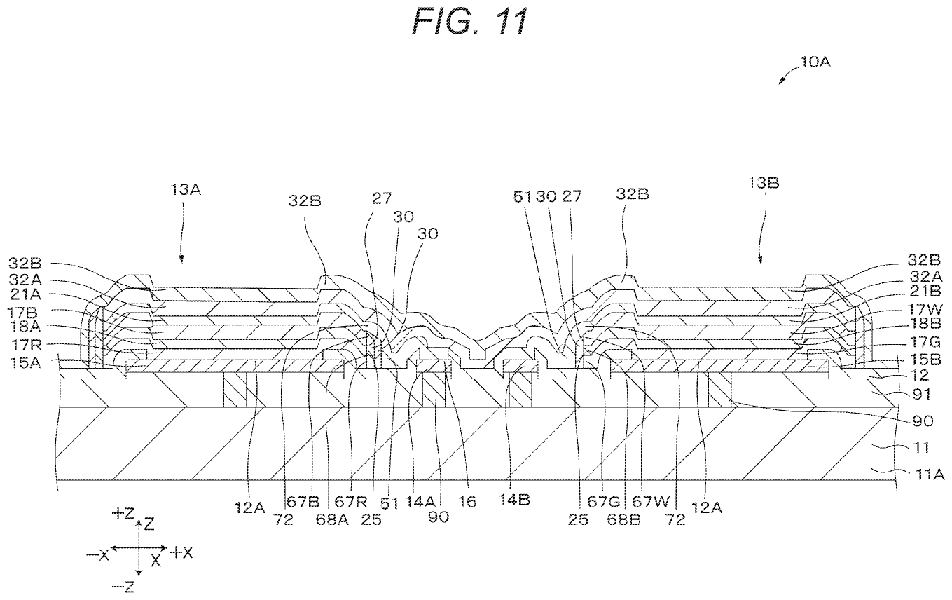

In the display device 10A of Modification 3 illustrated in the example of FIG. 10, in the laminated structure 13A, the organic EL layer 17R is disposed between the first electrode 15A and the second electrode 18A, and the organic EL layer 17G is disposed between the third electrode 21A and the second electrode 18A. In addition, in the laminated structure 13B, the organic EL layer 17B is disposed between the first electrode 15B and the second electrode 18B, and the organic EL layer 17G is disposed between the third electrode 21B and the second electrode 18B. The pixel corresponding to the laminated structure 13A includes two types of subpixels (subpixels 101R and 101G). The pixel corresponding to the laminated structure 13B includes two types of subpixels (subpixels 101G and 101B).

The display device 10A of Modification 3 may be similar to the display device 10A described in the first embodiment except for the above.

### (Effect)

The display device 10A of Modification 3 can obtain similar effects to those of the display device 10A described in the first embodiment.

### [Modification 4]

### (Configuration)

In the display device according to the first embodiment, the wiring 38 is provided as the electrode relay portion, but the electrode relay portion is not limited to the wiring 38. As illustrated in FIG. 11, the electrode relay portion may be constituted by an extending portion 51 extending from a predetermined position of an outer edge portion 72 (position corresponding to a sidewall 71) of the third electrode 21 (Modification 4). FIG. 11 is a cross-sectional view illustrating an example of a display device according to Modification 4 of the first embodiment.

In the display device 10A of Modification 4, the sidewall insulating layer 30 covers the sidewalls 67R, 68A, and 67B of the organic EL layer 17R, the second electrode 18A, and the organic EL layer 17B in the laminated structure 13A. The third electrode 21A extends outward from a predetermined position of the outer edge portion 72 of the third electrode 21A. At this time, a portion of the third electrode 21A extending outward from the position of the wall surface portion 25 forms the extending portion 51. The extending portion 51 passes over the upper end of the sidewall insulating layer 30, passes through the surface of the sidewall insulating layer 30, extends toward the drive substrate 11, and is electrically connected to the pad 14. At this time, the extending portion 51 is provided so as to pass over the outer surface of the wall surface portion 25 via the sidewall insulating layer 30. The extending portion 51 functions as an electrode relay portion. The upper surface of the third electrode 21A is covered with the protective layer 32A. Furthermore, the protective layer 32B is formed on the protective layer 32A.

### (Effect)

The display device 10A of Modification 1 can obtain similar effects to those of the display device 10A described in the first embodiment.

### [Modification 5]

In the display device 10A according to the first embodiment, the combination of the organic EL layers 17 arranged in the laminated structures 13A and 13B is not limited to the combination described above. For example, an organic EL layer that emits yellow light as emission light or an organic EL layer that emits near infrared light (NIR) as emission light may be provided between the first electrode 15 and the second electrode 18 or between the third electrode 21 and the second electrode 18. Examples of the light emitting in yellow include light having a dominant wavelength in a range of 570 nm to 585 nm. As the near infrared light, for example, light having a dominant wavelength in a range of 800 nm to 2500 nm can be exemplified.

### [Modification 6]

In the display device according to the first embodiment, as illustrated in FIG. 3, the insulating layer 12 is formed, but the insulating layer 12 may be omitted (not illustrated). In this case, the sidewall insulating layer 30 may be a layer that covers the wall surface portion 25 with the drive substrate 11 as a base end. In this case, the sidewall insulating layer 30 can also function as the insulating layer 12.

### 2 Second Embodiment

### [2-1 Configuration of Display Device]

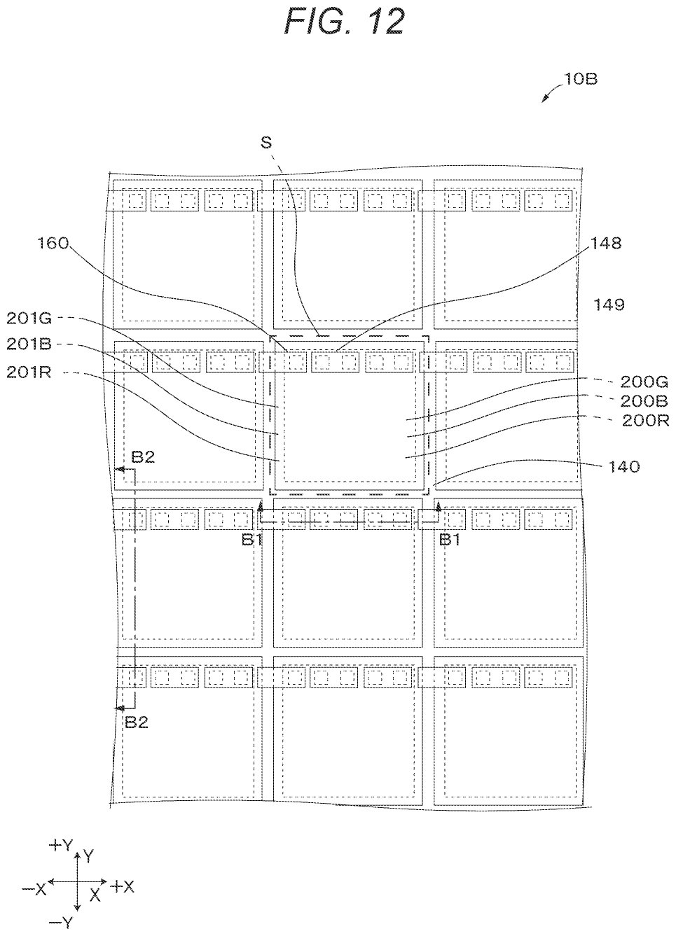

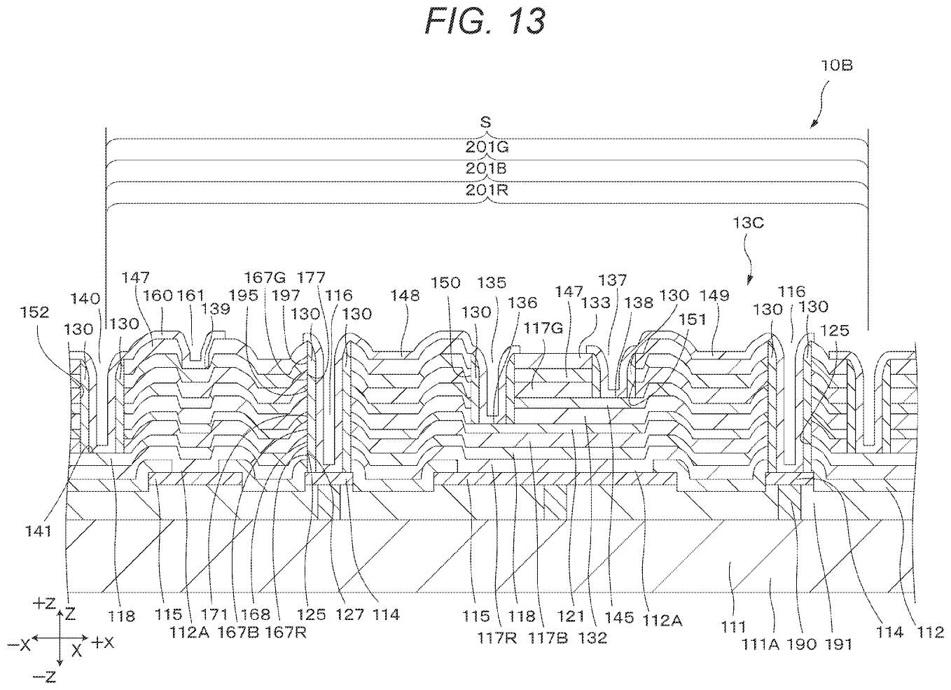

A display device 10B according to a second embodiment will be described with reference to FIGS. 12, 13, and the like. FIG. 12 is a plan view illustrating an example of arrangement of the pixels S of the display device 10B according to the second embodiment, and FIG. 13 is a schematic cross-sectional view illustrating a state of a cross section taken along line B-B in FIG. 12.

Note that, regarding the individual functions and materials of the drive substrate 11, the interlayer film 91, the contact plug 90, the pad 14, the first electrode 15, the second electrode 18, the third electrode 21, and the organic EL layer 17R described in the above first embodiment, and the types of the subpixels 101 and the types of the organic EL elements 100, similar ones may be adopted for the configurations and materials of drive substrates 111 and 211, interlayer films 191 and 291, contact plugs 190 and 290, pads 114 and 214, first electrodes 115 and 215, second electrodes 118 and 218, third electrode 121, and organic EL layers 117 and 217 used in the second embodiment and a third embodiment to be described later, and similar ones may be adopted for the subpixels 101 and the organic EL elements 100. Hereinafter, detailed description of configurations and materials similar to those of the first embodiment may be omitted. In addition, the preferable material and thickness range and formation method of the sidewall insulating layer 30 described in the first embodiment are similar for sidewall insulating layers 130 and 230 of the second embodiment and the third embodiment described later, and thus the description thereof will be omitted. In addition, each configuration of the subpixel 101 and the like using a generic term in the first embodiment may be similarly described using a generic term in each corresponding configuration in the second embodiment and the third embodiment. In the second embodiment, it is preferable to provide a similar configuration to the filling resin layer 104 and the counter substrate 105 illustrated in the first embodiment, but for convenience of description, description and illustration thereof are omitted.

The display device 10B includes a plurality of laminated structures 13C on a drive substrate 111. Similarly to the first embodiment, the laminated structure 13C includes a first electrode 115, an organic EL layer 117R as a first organic layer, a second electrode 118, an organic EL layer 117B as a second organic layer, and a third electrode 121. In the display device according to the second embodiment, the laminated structure 13C further includes a fourth electrode 145, an organic EL layer 117G as a third organic layer, and a fifth electrode 147 in this order on the third electrode 121.

### (Organic EL Element)

In the laminated structure 13C, a plurality of organic EL elements 200 is formed. A combination of the first electrode 115, the organic EL layer 117R, and the second electrode 118 forms an organic EL element 200R, and a combination of the second electrode 118, the organic EL layer 117B, and the third electrode 121 forms an organic EL element 200B. In addition, a combination of the fourth electrode 145, the organic EL layer 117G, and the fifth electrode 147 forms an organic EL element 200G.

In the display device 10B, as illustrated in FIGS. 12 and 13, the laminated structure 13C is formed for each pixel S, and in the pixel S, a subpixel 201R, a subpixel 201B, and a subpixel 201G are formed so as to overlap in the up-down direction in the laminated structure.

### (First Electrode)

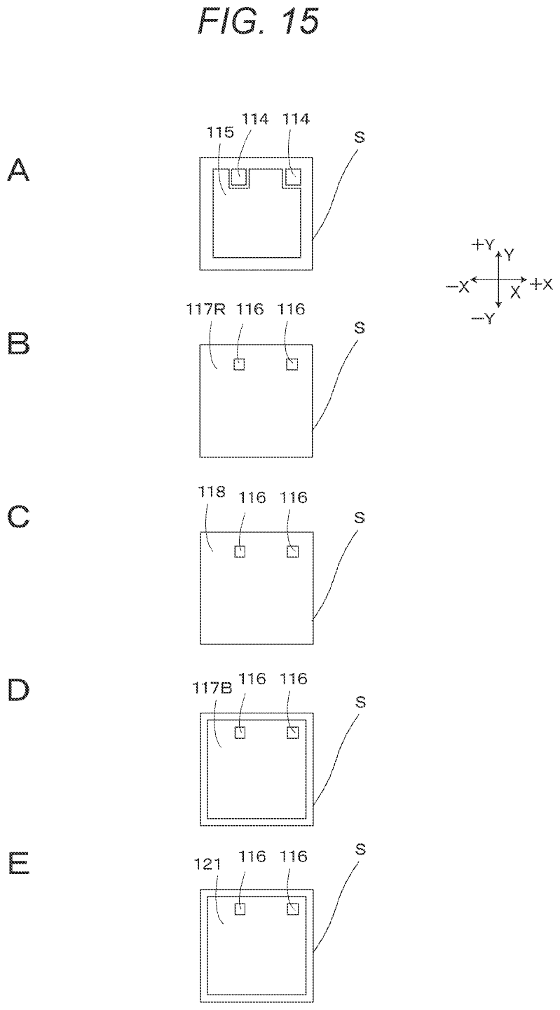

A plurality of first electrodes 115 is provided on the first surface side of the drive substrate 111. The plurality of first electrodes 115 is two-dimensionally arranged corresponding to the layout of the laminated structure 13C. As illustrated in FIG. 15A, one first electrode 115 is formed per one pixel S. Furthermore, in one pixel S, the first electrode 15 is formed in a region avoiding the pad 114 and in a region inside the pixel S.

The first electrode 115 is an anode. When a voltage is applied to the first electrode 115 and the second electrode 118, holes are injected from the first electrode 115 into the organic EL layer 117R.

### (Pad)

On the first surface side of the drive substrate 111, pads 114 and 114 having conductivity are arranged at two predetermined positions with respect to one pixel S. In the example of FIG. 15A, the positions of the pads 114 and 114 are provided at one position near the end edge of the pixel and at a position near the corner position, but are not limited to this arrangement. The pads 114 and 114 are electrically connected to the third electrode 121 and the fourth electrode 145.

### (Insulating Layer)

An insulating layer 112 having an opening 112A is formed between the adjacent first electrodes 115. The opening 112A is formed at the position of the first electrode 115.

### (Organic EL Layer)

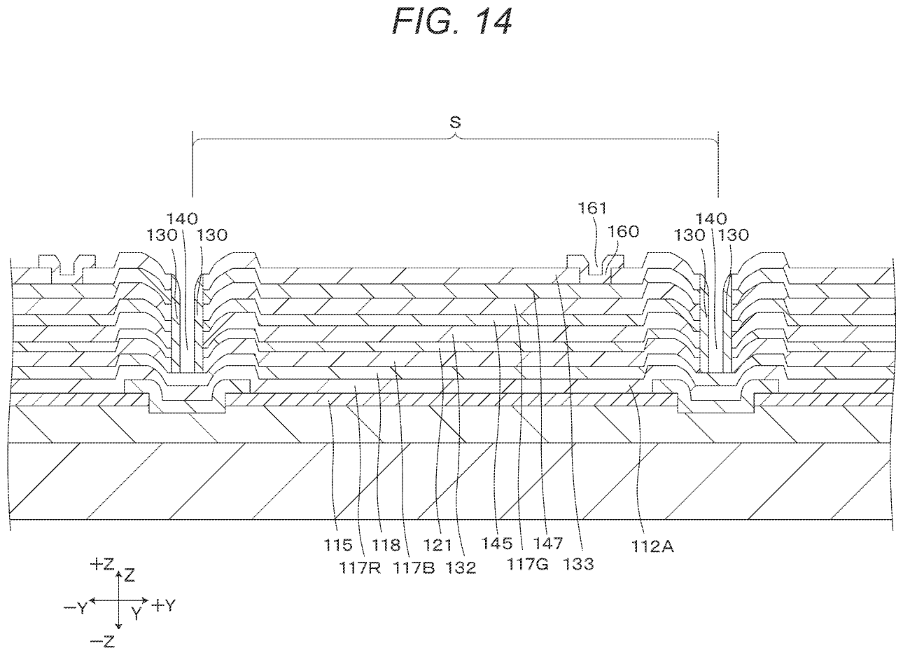

As illustrated in FIG. 13, the organic EL layer 117R is disposed between the first electrode 115 and the second electrode 118. The organic EL layer 117R covers the upper surface side of the first electrode 115 and the insulating layer 112. In the example of the display device 10B of FIG. 13, the organic EL layer 117R is formed in a range corresponding to the subpixel 201R as illustrated in FIG. 13. As illustrated in FIG. 14, the organic EL layer 117R is continuous in the Y-axis direction, and is formed on the entire surface of the pixel S except for a connection hole 116 as illustrated in FIG. 15B.

The organic EL layer 117B is disposed between the third electrode 121 and the second electrode 118. The organic EL layer 117B covers the upper surface side of the second electrode 118. As illustrated in FIG. 13, the organic EL layer 117B is formed in a range corresponding to the subpixel 201B. Since the shape of the organic EL layer 17B is separated between the adjacent pixels S to form a groove 140 as illustrated in FIG. 14, the organic EL layer is formed in a region inside the pixel S in the pixel S as illustrated in FIG. 15D. In addition, the organic EL layer 17B is formed in a region excluding the connection hole 116 as illustrated in FIG. 15B.

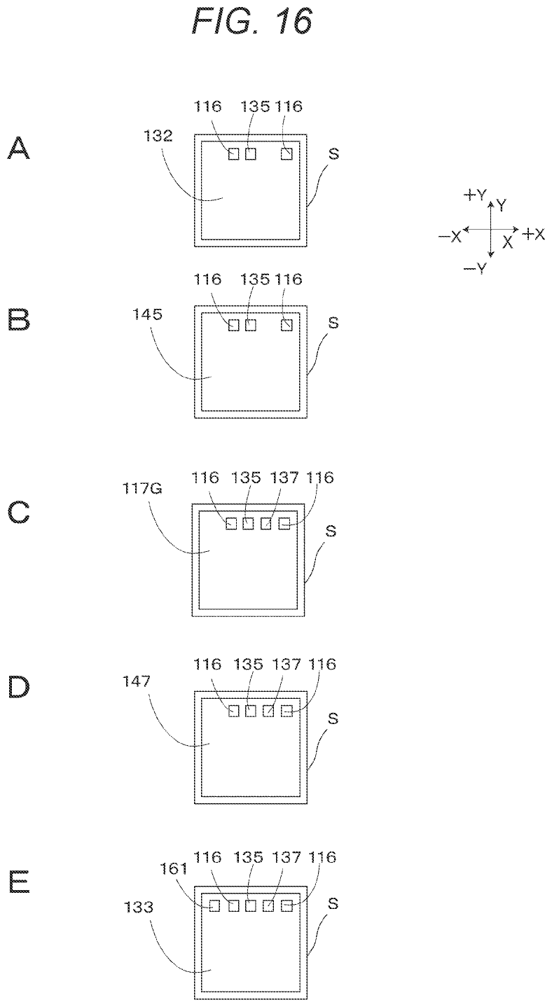

The organic EL layer 117G is disposed between the fourth electrode 145 and the fifth electrode 147. The organic EL layer 117G covers the fourth electrode 145. The organic EL layer 117G is formed in a range corresponding to the subpixel 201G. Since the shape of the organic EL layer 117G is separated between the adjacent pixels S to form the groove 140 as illustrated in FIG. 14, the organic EL layer is formed in a region inside the pixel S in the pixel S as illustrated in FIG. 16C. In addition, the organic EL layer 117G is formed in a region excluding connection holes 116, 135, and 137 as illustrated in FIG. 16C.

### (Second Electrode)

In the display device 10B, each of the second electrodes 118 is disposed on the first surface side of the first electrode 115. The second electrode 118 is a cathode. The second electrode 118 is a common electrode of the first electrode 115 and the third electrode 121. When a voltage is applied to the first electrode 115 and the second electrode 118, holes are injected from the first electrode 115 into the organic EL layer 117R. From the second electrode 118, electrons are injected into the organic EL layer 117R. As for the shape of the second electrode 118, as illustrated in FIG. 14, the organic EL layer 117R is continuous in the Y-axis direction, and is formed on the entire surface of the pixel S except for the connection hole 116 as illustrated in FIG. 15C.

### (Third Electrode)

The third electrode 121 is disposed on the first surface side of the organic EL layer 117B. The third electrode 121 is an anode. When a voltage is applied to the third electrode 121 and the second electrode 118, holes are injected from the third electrode 121 into the organic EL layer 117B. Electrons are injected from the second electrode 118 into the organic EL layer 117B. Since the shape of the third electrode 121 is separated between the adjacent pixels S as illustrated in FIG. 14, the third electrode is formed in a region inside the pixel S in the pixel S as illustrated in FIG. 15E. In addition, as illustrated in FIG. 15B, the third electrode 121 is formed in a region excluding the connection hole 116.

### (Fourth Electrode and Fifth Electrode)

In the display device 10B, the fourth electrode 145 is disposed on the first surface side of the third electrode 121. As described above, the fifth electrode 147 is disposed closer to the first surface side (the +Z direction side in FIG. 13) than the fourth electrode 145 with the organic EL layer 117G interposed therebetween.

In the example of FIG. 13, the fourth electrode 145 is an anode. In addition, the fifth electrode 147 is a cathode. When a voltage is applied to the fourth electrode 145 and the fifth electrode 147, holes are injected from the fourth electrode 145 into the organic EL layer 117G. Then, electrons are injected from the fifth electrode 147 into the organic EL layer 117G.

Since the shapes of the fourth electrode 145 and the fifth electrode 147 are separated between adjacent pixels S as illustrated in FIG. 14, as illustrated in FIGS. 16B and 16D, in one pixel S, they are formed in a region inside the pixel S. In addition, as illustrated in FIG. 16B, the fourth electrode 145 is formed in a region excluding the connection holes 116 and 135. As illustrated in FIG. 16D, the fifth electrode 147 is formed in a region excluding the connection holes 116 and 135.

The fourth electrode 145 and the fifth electrode 147 may be constituted by a similar material to the third electrode 121 and the second electrode 118, respectively.

In the display device 10B according to the second embodiment, the third electrode 121 and the fourth electrode 145 are electrically separated from each other. In the example of FIG. 13, a protective layer 132 is formed between the third electrode 121 and the fourth electrode 145, and the third electrode 121 and the fourth electrode 145 are electrically separated by the protective layer 132. Since the third electrode 121 and the fourth electrode 145 are electrically separated, current leakage between the third electrode 121 and the fourth electrode 145 can be suppressed.

### (Protective Layer)

The protective layer 132 is provided in a region inside the pixel S so as to cover the upper surface of the third electrode 121 except for the regions of the connection holes 116 and 135 as illustrated in FIG. 16A per pixel S. The protective layer 132 is constituted by an insulating material. The protective layer 132 may be constituted by a similar material to the protective layers 32A and 32B described in the first embodiment.

In addition, a protective layer 133 is formed on the fifth electrode 147. As illustrated in FIG. 16E, the protective layer 133 covers the upper surface of the fifth electrode 147 except for the regions of the connection holes 116, 135, and 137. The protective layer 133 may be constituted by a similar material to the protective layer 132. The protective layer 132 prevents exposure of the fifth electrode 147 to the outside air.

### (Wall Surface Portion)

A wall surface portion 125 is formed in at least a part of the laminated structure 13C. The wall surface portion 125 is a portion having, at least in part, a connecting surface 127 in which a sidewall 167R of the organic EL layer 117R, a sidewall 168 of the second electrode 118, and a sidewall 167B of the organic EL layer 117B are connected. In the example of the display device 10B illustrated in FIG. 13, the wall surface portion 125 is formed on the peripheral wall portion of the connection hole 116 of the pad 114. The connection hole 116 is a hole portion extending from the upper surface of the protective layer 133 toward the drive substrate 111, and exposes the upper surface of the pad 114.

In the example of FIG. 13, in the portion of the connecting surface 127, the sidewall 167R, the sidewall 168, and the sidewall 167B are aligned in the up-down direction (Z-axis direction). Therefore, the periphery of the pad 114 can be used as a light emitting region, and the aperture ratio of the display device 10B is easily improved. From this viewpoint, on the connecting surface 127 of the wall surface portion 125, the sidewall 167R, the sidewall 168, and the sidewall 167B are preferably aligned flush with each other.

In addition, the wall surface portion 125 preferably has an alignment surface 177 in which the sidewall 171 of the third electrode 121, the sidewall 195 of the fourth electrode 145, and the sidewall 167G of the organic EL layer 117G are arranged along the surface direction of the connecting surface 127. In the example of the connecting surface 127 of the wall surface portion 125 illustrated in FIG. 13, the sidewall 167R, the sidewall 168, and the sidewall 167B are arranged to be flush with each other to form the connecting surface 127 in this order from the lower side to the upper side, and the alignment surface 177 in which the sidewall 171, the sidewall 195, and the sidewall 167G are arranged is formed at a position along the surface direction of the connecting surface 127 (position on the +Z direction side along the surface of the connecting surface 127). It is suitable that this alignment surface 177 is also aligned to be flush. Note that, in the example of FIG. 13, the sidewall of the protective layer 132 is interposed between the sidewall 171 and the sidewall 195 in the alignment surface 177, and the sidewall 171, the sidewall of the protective layer 132, the sidewall 195, and the sidewall 167G are aligned in the up-down direction.

### (Sidewall Insulating Layer)

In the display device 10B, the sidewall insulating layer 130 is provided on the outer surface of the wall surface portion 125. The sidewall insulating layer 130 formed in the laminated structure 13C covers the sidewall 167R, the sidewall 168, the sidewall 167B, the sidewall 171, the sidewall 195, and the sidewall 167G on the outer surface at the position of the connecting surface 127 of the wall surface portion 125, thereby restricting the organic EL layer 117R, the second electrode 118, and the organic EL layer 117B from being exposed to the external environment. Note that, in the example of FIG. 13, the sidewall insulating layer 130 is preferably formed so as to further cover the sidewall 197 of the fifth electrode 147 and the sidewalls of the protective layers 132 and 133. With such a formation, it is possible to more reliably suppress the possibility that wirings 148 and 149 described later come into contact with the fifth electrode 147 and the like.

The sidewall insulating layer 130 may be a single layer or a multilayer. In the example of FIG. 13, the sidewall insulating layer 130 is formed as a single layer on the wall surface portion 125 of the laminated structure 13B.

### (Connection Hole)

Connection holes 135, 137, and 161 are formed in the laminated structure 13B. The connection hole 135 is a hole portion extending from the upper surface of the protective layer 133 toward the drive substrate 111, and exposes the upper surface 136 of the third electrode 121. The connection hole 137 is a hole portion extending from the upper surface of the protective layer 133 toward the drive substrate 111, and exposes the upper surface 138 of the fourth electrode 145. The connection hole 161 is a hole portion extending from the upper surface of the protective layer 133 toward the drive substrate 111, and exposes the upper surface 139 of the fifth electrode 147.

### (Erected Surface Portion)

In addition to the wall surface portion 125, the sidewall insulating layer 130 is preferably formed on other erected surface portions 150, 151, and 152 as illustrated in the example of FIG. 13. The erected surface portions 150 and 151 are inner peripheral surface portions of the connection holes 135 and 137.

In the example of FIG. 13, the sidewall insulating layer 130 is formed from the third electrode 121 to the position of the protective layer 133 on the erected surface portion 150 forming the inner peripheral surface of the connection hole 135.

The sidewall insulating layer 130 is formed from the fourth electrode 145 to the position of the protective layer 133 on the erected surface portion 151 forming the inner peripheral surface of the connection hole 137.

### (Groove)

In addition, the sidewall insulating layer 130 is preferably formed on the erected surface portion 152. The erected surface portion 152 is a groove peripheral wall portion formed in the groove 140. As illustrated in FIG. 12, the groove 140 is formed so as to surround the outer periphery of the pixel S, extends from the upper surface of the protective layer 133 toward the drive substrate 111, and forms an exposed portion 141 that exposes the upper surface portion of the second electrode 118 and exposes the upper surface of at least a part of the second electrode 118. The groove 140 forms the erected surface portion 152 rising in a direction away from the drive substrate 111 (direction away from the substrate 111A) (+Z direction) with the exposed portion 141 as a bottom surface of the groove and an outer end edge of the exposed portion 141 as a base end. The sidewall insulating layer 130 is formed on at least a part of the erected surface portion 152. In the example of FIG. 13, the sidewall insulating layer 130 is formed over the entire erected surface portion 152 along the up-down direction.

Since the sidewall insulating layer 130 is also formed on each of the erected surface portions 150, 151, and 152 in this manner, it is possible to more reliably suppress the possibility that wirings 148, 149, and 160 described later come into contact with the fifth electrode 147, the organic EL layer 117G, and the like.

Note that, in addition to the connection holes 135 and 137, the connection hole 161 is formed as a hole portion extending from the upper surface of the protective layer 133 toward the drive substrate 111.

### (Wiring)

In the display device 10B, the wiring 148 is provided as the first electrode relay portion and the wiring 149 is provided as the second electrode relay portion on the upper surface side of the protective layer 133. The wiring 148 extends from the third electrode 121 toward the drive substrate 111 side, and is electrically connected to the pad 114 on the drive substrate 111.

The wiring 148 is connected to the upper surface 136 side of the third electrode 121 in the connection hole 135. Then, the wiring 148 extends from the connection hole 135 along the surface of the protective layer 133, passes through the outer surface side of the wall surface portion 125, and extends toward the pad 114. The sidewall insulating layer 130 is interposed between the wiring 148 and the wall surface portion 125. The third electrode 121 is electrically connected to the pad 114 via the wiring 148.

The wiring 149 extends from the fourth electrode 145 toward the drive substrate 111 side, and is electrically connected to the pad 114 on the drive substrate 111.

The wiring 149 is connected to the upper surface 138 side of the fourth electrode 145 in the connection hole 137. Then, the wiring 149 extends from the connection hole 137 along the surface of the protective layer 133, passes through the outer surface side of the wall surface portion 125, and extends toward the pad 114. The sidewall insulating layer 130 is interposed between the wiring 149 and the wall surface portion 125. The fourth electrode 145 is electrically connected to the pad 114 via the wiring 149.

In addition to the above, the wiring 160 is provided as the third electrode relay portion. The wiring 160 extends from the fifth electrode 147 toward the drive substrate 111 side, more specifically, extends toward the exposed portion 141 of the second electrode 118. The wiring 160 is connected to the upper surface 139 side of the fifth electrode 147 in the connection hole 161. Then, the wiring 160 extends from the connection hole 161 along the surface of the protective layer 133, further passes over the outer surface of the erected surface portion 152, and extends toward the exposed portion 141 of the second electrode 118. The sidewall insulating layer 130 is interposed between the wiring 160 and the erected surface portion 152. The fifth electrode 147 is electrically connected to the exposed portion 141 of the second electrode 118 via the wiring 160.

### [2-2 Effects]

According to the display device 10B according to the second embodiment, similar effects to those of the first embodiment can be obtained.

### 3 Third Embodiment

### [3-1 Configuration of Display Device]

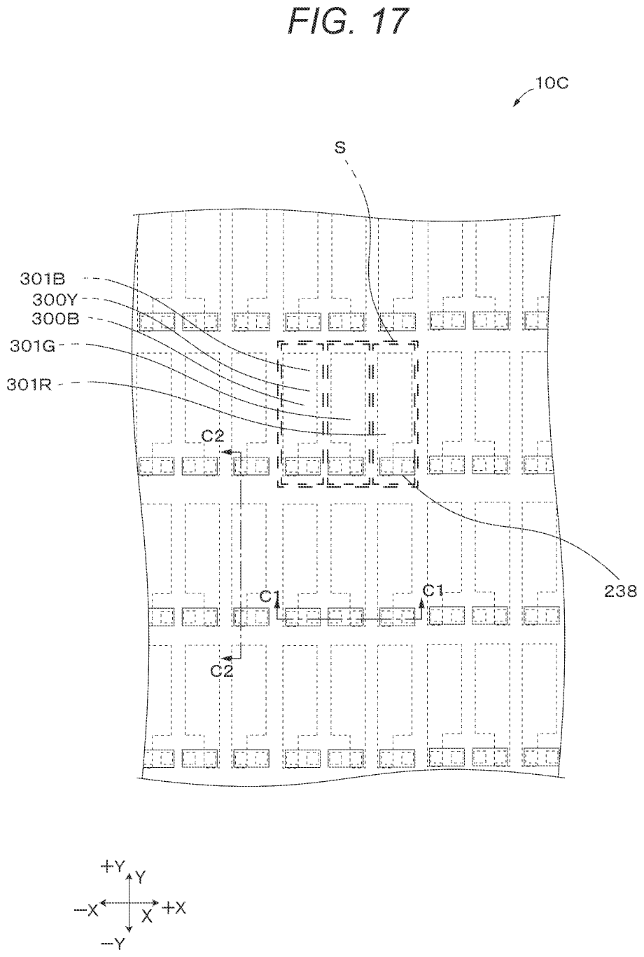

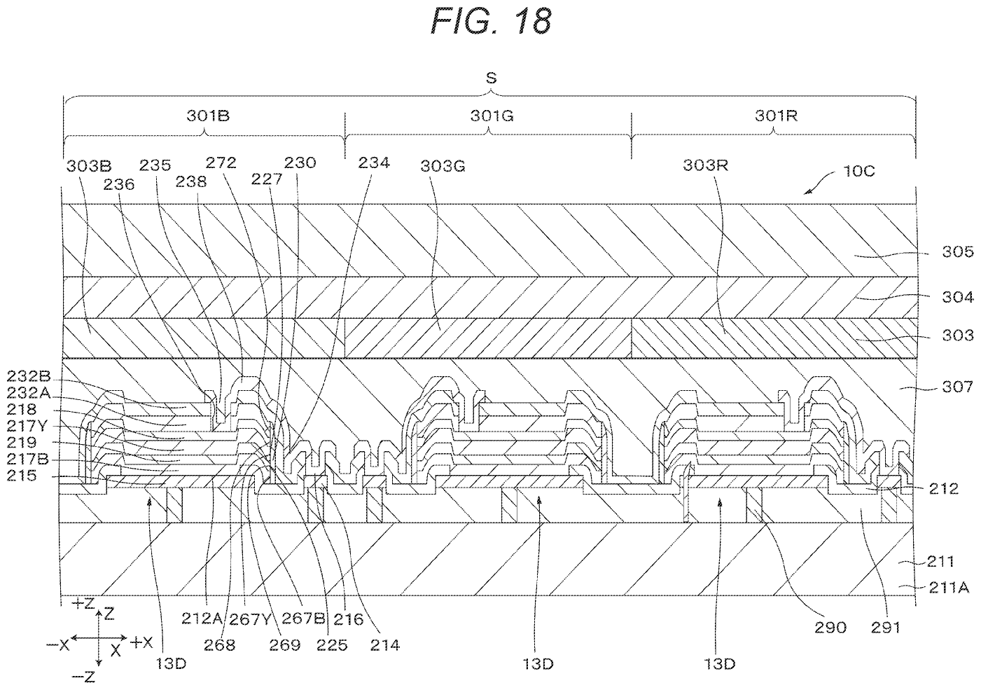

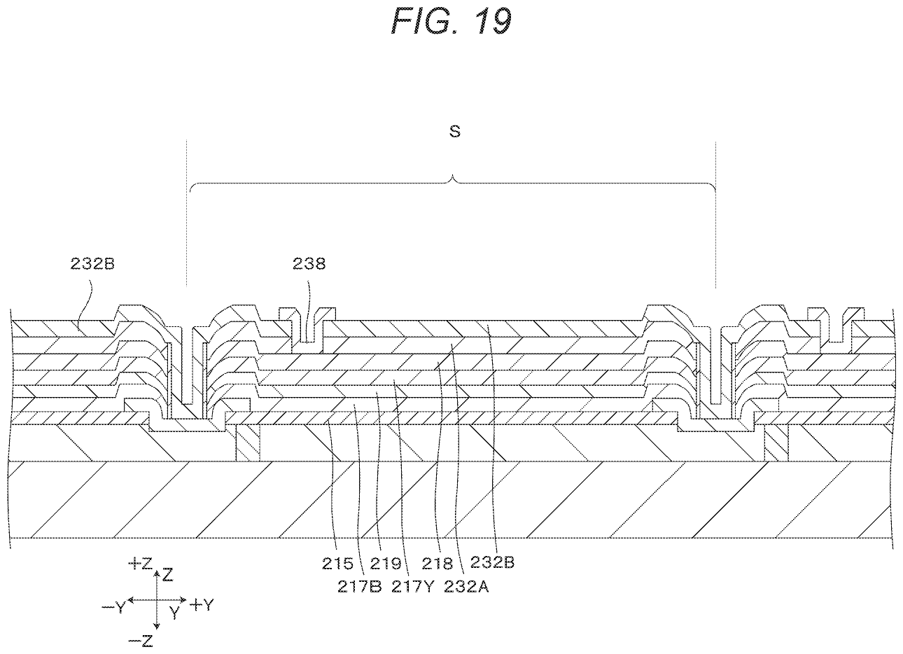

A display device 10C according to a third embodiment will be described with reference to FIGS. 17, 18, 19, and the like. FIG. 17 is a plan view illustrating an example of arrangement of the pixels S of the display device 10C according to the third embodiment. FIG. 18 is a schematic cross-sectional view illustrating a state of a cross section taken along line C1-C1 in FIG. 17. FIG. 19 is a schematic cross-sectional view illustrating a state of a cross section taken along line C2-C2 in FIG. 17.

The display device 10C illustrated in FIG. 17 includes a plurality of laminated structures 13D per pixel S. In the example of FIG. 17, in the display device 10C, subpixels 301B, 301G, and 301R are provided in one pixel S, and a laminated structure 13D is provided for each subpixel 301.

The laminated structure 13D illustrated in FIG. 17 includes a first electrode 215, an organic EL layer 217B as a first organic layer, a charge generation layer 219, an organic EL layer 217Y as a second organic layer, and a second electrode 218 in this order.

### (Organic EL Element)

In the laminated structure 13D, a plurality of organic EL elements 300 is formed. A combination of the first electrode 215, the organic EL layer 217B, and the charge generation layer 219 functions as an organic EL element 300B, and a combination of the charge generation layer 219, the organic EL layer 217Y, and the second electrode 118 functions as an organic EL element 300Y. In the example of the laminated structure 13D illustrated in FIG. 18, white light can be formed by a combination of the organic EL element 300Y and the organic EL element 300B. In the subpixel 301B, blue light is formed by white light passing through a color filter layer 303B. In the subpixels 301G and 301R, green light and red light are formed similarly to the subpixel 301B, respectively.

In the display device 10B, the laminated structure 13D is formed at positions corresponding to the subpixel 301R, the subpixel 301B, and the subpixel 301G, respectively.

### (First Electrode)

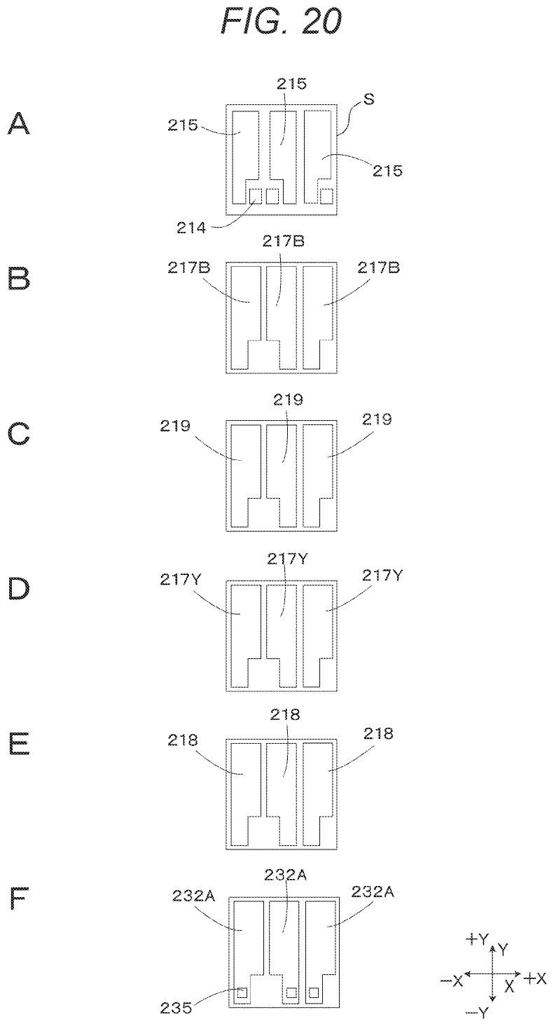

A plurality of first electrodes 215 is provided on the first surface side of the drive substrate 211. The plurality of first electrodes 215 is two-dimensionally arranged corresponding to the layout of the laminated structure 13C. As illustrated in FIG. 20A, in one pixel S, three pixels are formed side by side while avoiding the position of the pad 114.

The first electrode 215 is an anode. When a voltage is applied to the first electrode 215 and the second electrode 218, holes are injected from the first electrode 215 into the organic EL layer 217B.

### (Pad)

On the first surface side (+Z direction side) of the drive substrate 211 having the substrate 211A, a pad 214 having conductivity is disposed at a predetermined position for each laminated structure 13D. As illustrated in FIG. 20A, the position of the pad 214 is provided at a position corresponding to the vicinity of the corner position of each subpixel 301, but is not limited to this arrangement.

### (Insulating Layer)

An insulating layer 212 having an opening 212A is formed between the adjacent first electrodes 215. The opening 212A is formed at the position of the first electrode 215. In addition, in the insulating layer 212, a connection hole 216 is formed at the position of the pad 214.

### (Organic EL Layer)

As illustrated in FIG. 18, the organic EL layer 217B is disposed between the first electrode 215 and the charge generation layer 219. The organic EL layer 217B covers the upper surface side of the first electrode 215 and the insulating layer 212. As illustrated in FIG. 18, in the example of the display device 10C, the organic EL layer 217B is formed at positions corresponding to the subpixels 301R, 301B, and 301G in a state of being separated from each other for each subpixel 301.

The organic EL layer 217Y is disposed between the charge generation layer 219 and the second electrode 218. The organic EL layer 217Y covers the upper surface side of the charge generation layer 219. As illustrated in FIG. 18, the organic EL layer 217Y is formed at a position corresponding to each of the subpixels 301R, 301B, and 301G in a state of being separated from each other for each subpixel 301.

Since the shapes of the organic EL layer 217B and the organic EL layer 217Y are separated between adjacent pixels S to form the groove 140 as illustrated in FIG. 19, the organic EL layer is formed in a region inside the pixel S in the pixel S as illustrated in FIGS. 20B and 20D. The charge generation layer 219 and the second electrode 218 to be described later are also formed in similar shapes to the organic EL layer 217B and the organic EL layer 217Y (FIG. 20C and FIG. 20E).

### (Charge Generation Layer)

In the display device 10B, the charge generation layer 219 is disposed between the first electrode 215 and the second electrode 218. When a voltage is applied, the charge generation layer 219 generates holes and electrons. Electrons generated in the charge generation layer 219 when a voltage is applied to the first electrode 215 and the second electrode 218 are injected into the organic EL layer 217B, and holes generated in the charge generation layer 219 are injected into the organic EL layer 217Y. As a material of the charge generation layer 219, a metal oxide such as MoO₃, V₂O₅, or WO₃, an organic material having a strong electron acceptor property, or the like can be suitably used.

### (Second Electrode)

In the display device 10B, each of the second electrodes 218 is disposed on the first surface side of the first electrode 215. The second electrode 218 is a cathode. When a voltage is applied to the first electrode 215 and the second electrode 218, the second electrode 218 injects electrons into the organic EL layer 217Y.

The second electrode 218 is provided for each subpixel 301, and is connected to the pad 214 by wiring described later. Since the second electrode 218 is connected to the pad 214 for each subpixel 301, the pixels S adjacent to each other are separated in both the X-axis direction and the Y-axis direction as illustrated in FIGS. 18 and 19.

### (Wall Surface Portion)

A wall surface portion 225 is formed in at least a part of the laminated structure 13D. The wall surface portion 225 is a portion having, at least in part, a connecting surface 227 in which a sidewall 267B of the organic EL layer 217B, a sidewall 269 of the charge generation layer 219, and a sidewall 267Y of the organic EL layer 217Y are connected. The wall surface portion 225 is formed at a portion of the end surfaces of the laminated structure 13D facing each other, the portion being adjacent to each other with the pad 214 interposed therebetween. In the example of FIG. 18, in the portion of the connecting surface 227, the sidewall 267B, the sidewall 269, and the sidewall 267Y are aligned in the up-down direction, and the aperture ratio of the display device 10C is easily improved. From this viewpoint, on the connecting surface 227 of the wall surface portion 225, the sidewall 267B, the sidewall 269, and the sidewall 267Y are preferably aligned flush with each other. In addition, the connecting surface 227 is preferably formed in a state in which a sidewall 268 of the second electrode 218 is further connected. In the example of the connecting surface 227 of the wall surface portion 225 illustrated in FIG. 18, the sidewall 267B, the sidewall 269, the sidewall 267Y, and the sidewall 268 are arranged to be flush with each other in order from the lower side to the upper side.

### (Sidewall Insulating Layer)

In the display device 10C, the sidewall insulating layer 230 is provided on the outer surface of the wall surface portion 225. The sidewall insulating layer 230 formed in the laminated structure 13D covers the sidewall 267B, the sidewall 269, and the sidewall 267Y, thereby restricting the organic EL layer 217B, the charge generation layer 219, and the organic EL layer 217Y from being exposed to an external environment. The sidewall insulating layer 230 may be formed so as to further cover the sidewall 268 of the second electrode 218.

The sidewall insulating layer 230 may be a single layer or a multilayer. In the example of FIG. 18, the sidewall insulating layer 230 is formed as a single layer on the wall surface portion 225.

### (Protective Layer)

Protective layers 232A and 232B are formed on the second electrode 218. The protective layer 232A is provided so as to cover the second electrode 218. Then, the protective layer 232B is provided so as to further cover the first surface side of the protective layer 232A.

In the example of FIG. 18, the protective layer 232A covers the upper surface of the second electrode 218. The sidewall of the protective layer 232A is covered with the sidewall insulating layer 230. The protective layer 232A is disposed for each subpixel 301 in plan view of the display device 10C.

In addition, the protective layer 232B covers the upper surface side of the protective layer 232A, and further covers the outer surface of the sidewall insulating layer 230. In the example of FIG. 18, a portion of the protective layer 232B covering the sidewall insulating layer 230 is an insulating auxiliary portion 234. The insulating auxiliary portion 234 reinforces insulation by the sidewall insulating layer 230. The protective layer 232B extends in the X direction and the Y direction in plan view of the display device 10C, and is a layer common to all the pixels.

In addition, a connection hole 235 penetrating the protective layers 232A and 232B is formed in the protective layers 232A and 232B. In one pixel S, as illustrated in FIG. 20F, one connection hole 235 is provided corresponding to each laminated structure 13D. In addition, in the connection hole 235, the upper surface 236 side of the second electrode 218 is exposed. The formation of the connection hole 235 in the protective layers 232A and 232B can be realized by appropriately using a method such as an etching method.

### (Wiring)

In the display device 10C, a wiring 238 is provided as an electrode relay portion on the upper surface side of the protective layer 232B. The wiring 238 extends from the second electrode 218 toward the drive substrate 211 side, which is the substrate side. In the example of FIG. 18, the wiring 238 is connected to the upper surface 236 side of the second electrode 218 in the connection hole 235. Then, the wiring 238 passes over the outer surface of the wall surface portion 225 from the connection hole 235 and extends along the surface of the protective layer 232B toward the pad 214. At this time, the sidewall insulating layer 230 is interposed between the wiring 238 and the wall surface portion 225. The wiring 238 is electrically connected to the pad 214 of the drive substrate 211.

### (Planarizing Layer)

A planarizing layer 307 may be formed on the protective layer 232B and the wiring 238. The planarizing layer 307 can planarize the first surface. Examples of the planarizing layer 307 include an ultraviolet curable resin and a thermosetting resin. In addition, a protective film may be formed by CVD, an ALD method, or the like before the planarizing layer 307 is formed.

### (Color Filter Layer)

A color filter layer 303 is provided on the planarizing layer 307. The color filter layer 303, the color filter layer 303 may be provided according to the subpixel 301. For example, as the color filter layer 303 of the display device 10C illustrated in FIG. 18, color filter layers 303R, 303G, and 303B corresponding to the subpixels 301R, 301G, and 301B are provided. Hereinafter, in a case where the color filter layers 303R, 303G, and 303B are not distinguished, the color filter layers 303R, 303G, and 303B are collectively referred to as a color filter layer 303.

### (Filling Resin Layer)

In the display device 10C, a filling resin layer 304 is formed so as to cover the color filter layer 303. The filling resin layer 304 can protect the color filter layer 303 and planarize the first surface side (+Z direction side) of the color filter layer 303. The filling resin layer 304 can have a function as an adhesive layer for bonding the color filter layer 303 and the counter substrate 305 described later. Examples of the filling resin layer 304 include ultraviolet curable resin, thermosetting resin, and the like.

### (Counter Substrate)

The counter substrate 305 is provided on the filling resin layer 304 in a state of facing the drive substrate 11. The counter substrate 305 seals the organic EL element 300 together with the filling resin layer 304. The counter substrate 305 is preferably constituted by a material such as glass.

### [3-2 Effects]

According to the display device according to the third embodiment, similar effects to those of the first embodiment can be obtained.

### [3-3 Modifications]

The display device according to the third embodiment is not limited to those described above, and may be formed, for example, as illustrated in the following modifications.

### [Modification 1]

In the display device 10C according to the third embodiment, for each of the subpixel 301R, the subpixel 301B, and the subpixel 301G, the organic EL layers 217 of the same color may be arranged between the first electrode 215 and the charge generation layer 219 and between the charge generation layer 219 and the organic EL layer 217B. In the subpixel 301R, the organic EL layer 217R is disposed between the first electrode 215 and the charge generation layer 219 and between the charge generation layer 219 and the second electrode 218. In the subpixel 301B, the organic EL layer 217B is disposed between the first electrode 215 and the charge generation layer 219 and between the charge generation layer 219 and the second electrode 218. In the subpixel 301G, the organic EL layer 217G is disposed between the first electrode 215 and the charge generation layer 219 and between the charge generation layer 219 and the second electrode 218. Furthermore, in this case, these other configurations are similar to those of the display device 10C according to the third embodiment described above. Note that, in Modification 1, the color filter layer 303 may be omitted or provided.

### [Modification 2]

In the display device 10C according to Modification 1 of the third embodiment, a resonator structure may be formed for each of the subpixel 301R, the subpixel 301B, and the subpixel 301G.

The resonator structure is a cavity structure, and is a structure that resonates emission light from the organic EL layer 217 disposed between the first electrode 215 and the charge generation layer 219 or between the charge generation layer 219 and the second electrode 218. In the display device 10C, the resonator structure is formed in the organic EL element 300, and for example, the first electrode 215, the organic EL layer 217, and the second electrode 218 form the resonator structure. Note that, resonating the emission light from the organic EL layer 217 means resonating the light of a specific wavelength included in the emission light.

Next, an example in an embodiment of a method of manufacturing the display device 10A according to an embodiment (first embodiment) of the present disclosure will be described.

### 4 Method for Manufacturing Display Device

### 4-1 First Embodiment of Manufacturing Method

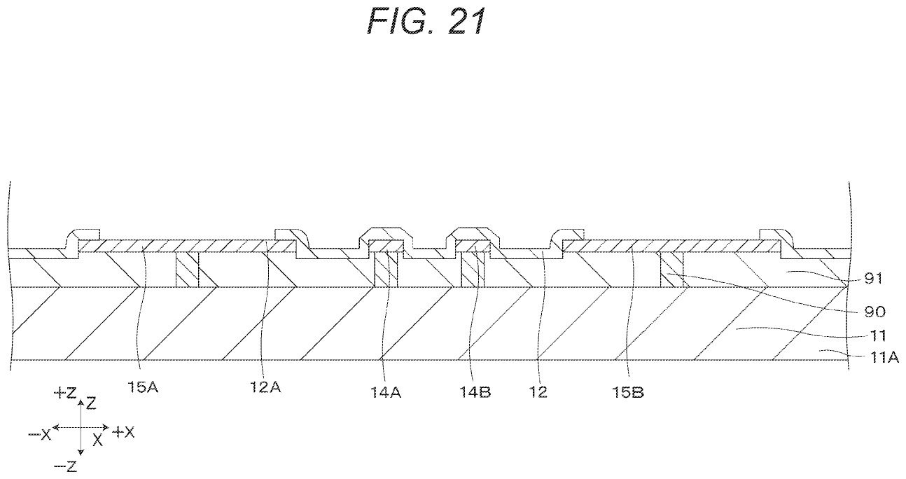

In the first embodiment of the manufacturing method, as illustrated in FIG. 21, an interlayer film 91 and a contact plug 90 are formed on a first surface of a drive substrate 11 in which a drive circuit is formed on a substrate 11A.

A first electrode 15 and a pad 14 are formed on the interlayer film 91, and an insulating layer 12 is further laminated (FIG. 21). A plurality of first electrodes 15 and a plurality of pads 14 are formed according to the arrangement of the subpixels 101, and openings 12A are formed in the insulating layer 12 according to the pattern of the subpixels 101. The first electrode 15, the pad 14, and the insulating layer 12 can be formed by, for example, a sputtering method, chemical vapor deposition (CVD), atomic layer deposition (ALD), or the like. At this time, the opening 12A is formed at a position of the first electrode 15.

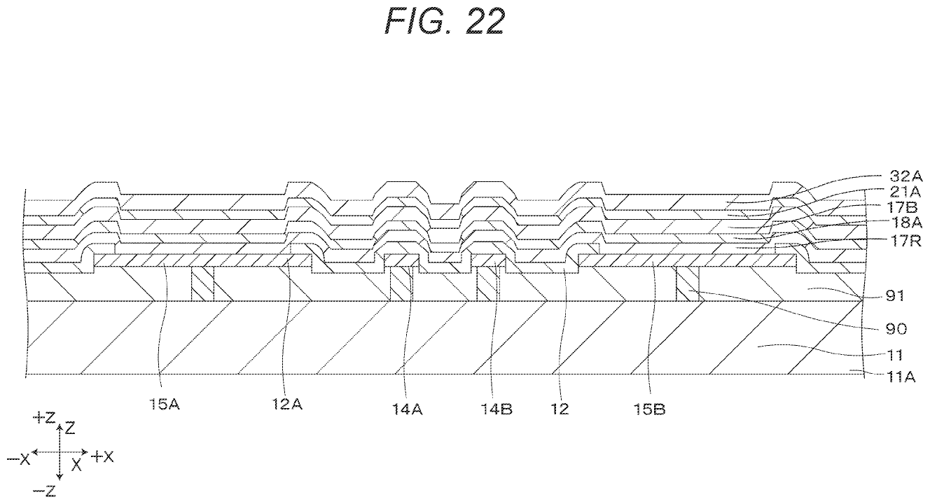

As illustrated in FIG. 22, an organic EL layer 17R as a first organic layer, a second electrode 18A, an organic EL layer 17B as a second organic layer, a third electrode 21A, and a protective layer 32A are formed on the first electrode 15 and the insulating layer 12. In a case where the organic EL layer 17 has, for example, a laminated structure in which a hole transport layer, a light emitting layer, and an electron transport layer are laminated in this order, layers that form the electron transport layer, the light emitting layer, and the hole transport layer are sequentially laminated. Examples of the method for forming these layers include coating methods such as a vacuum vapor deposition method, a spin coating method, and a die coating method.

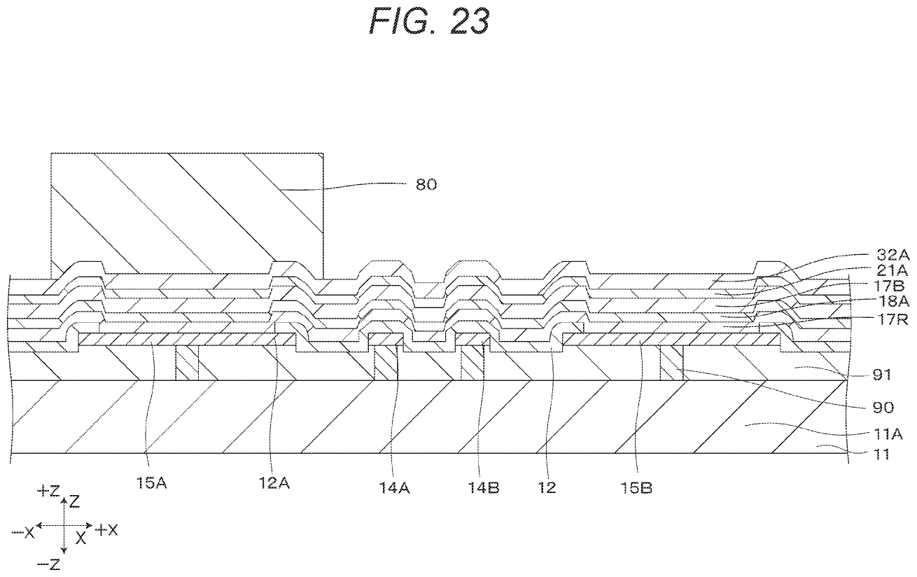

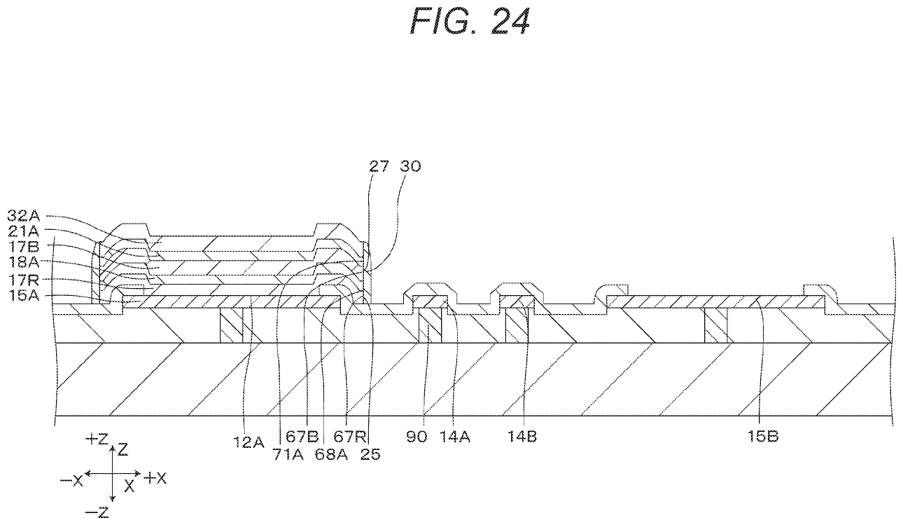

As illustrated in FIG. 23, a resist 80 corresponding to the arrangement pattern of the laminated structure 13A is formed, and dry etching (first dry etching processing) is performed to form the wall surface portion 25 at a position corresponding to the resist pattern (FIG. 24). The first dry etching processing is a batch formation process of collectively etching the organic EL layer 17R as the first organic layer, the second electrode 18A, the organic EL layer 17B as the second organic layer, the third electrode 21A, and the protective layer 32A. In addition, at this time, the sidewall insulating layer 30 is formed on the wall surface portion 25 side of the laminated structure 13A so as to cover the wall surface portion 25. The sidewall insulating layer 30 can be formed by, for example, processing a layer formed by a CVD method, an ALD method, or the like by lithography, etching, or the like, or processing by a sidewall process or the like. In addition, the sidewall insulating layer 30 may be formed by deposition or the like at the time of dry etching during batch formation processing. Note that, in the example of FIG. 24, the pattern of the resist 80 is a stripe-shaped pattern including the arrangement region of the laminated structure 13A and extending in the Y-axis direction, and at the stage of the first dry etching processing, the etched layers (organic EL layer 17R, second electrode 18A, organic EL layer 17B, third electrode 21A, and protective layer 32A) are also stripe-shaped.

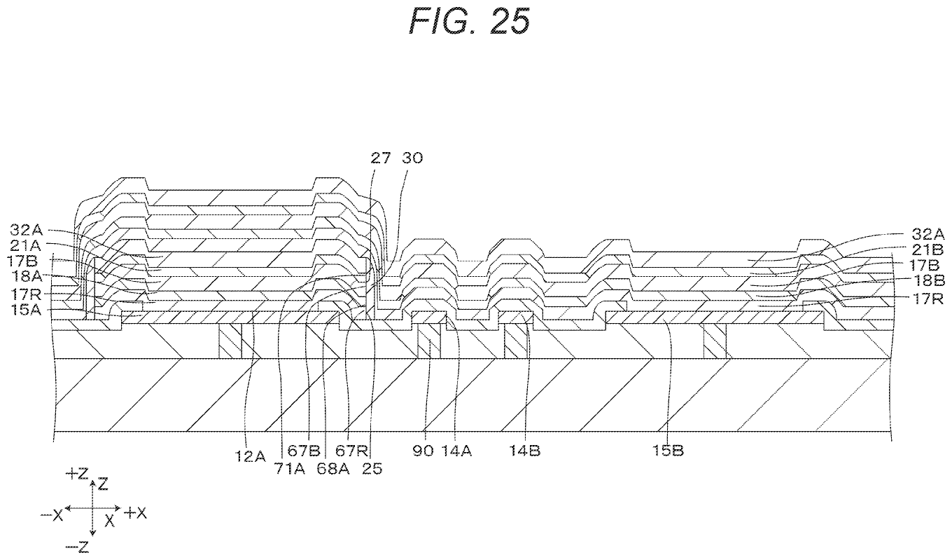

After the first dry etching processing is performed, as illustrated in FIG. 25, one surface of the organic EL layer 17G as a third organic layer, the second electrode 18B, the organic EL layer 17W as a second organic layer, the third electrode 21B, and the protective layer 32A is formed on the surface on the first surface side.

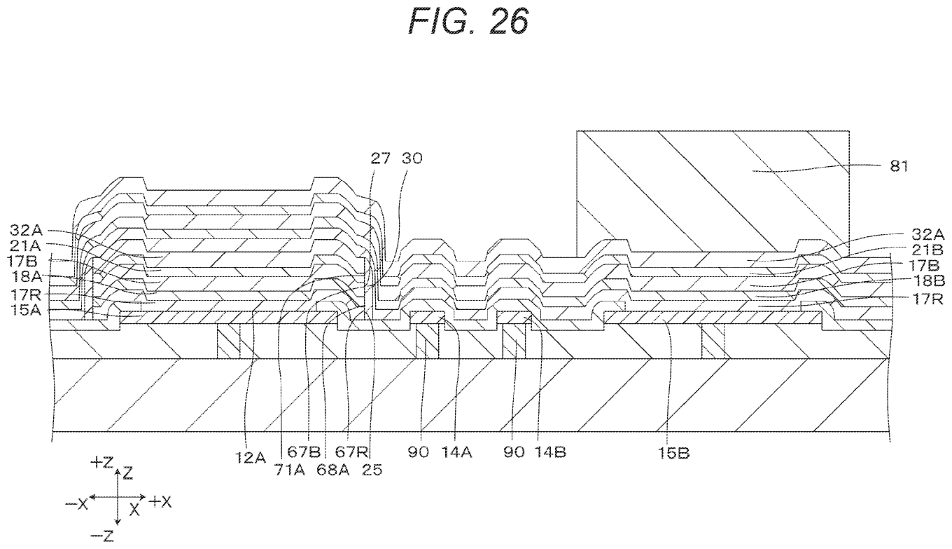

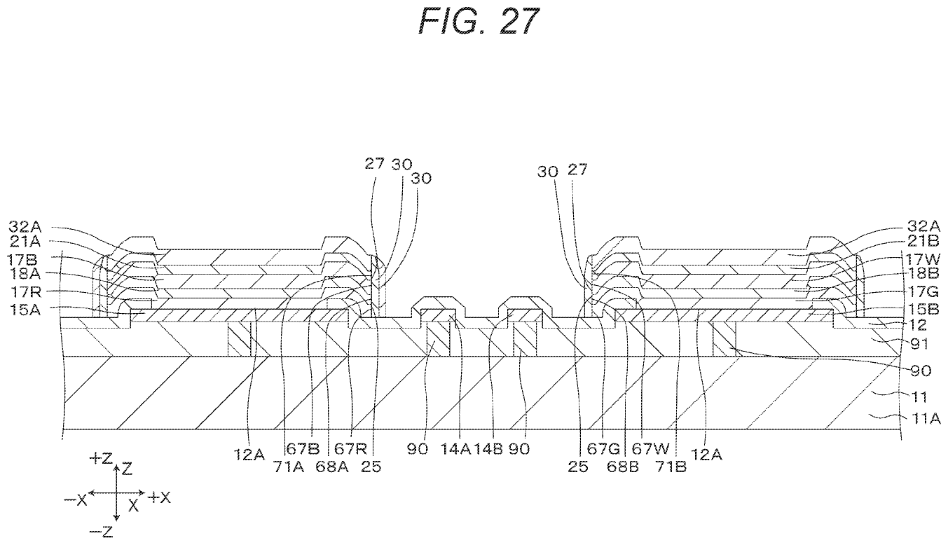

By forming the resist 81 corresponding to the arrangement pattern of the laminated structure 13B (FIG. 26) and performing dry etching (second dry etching processing), the wall surface portion 25 is formed at a position corresponding to the resist pattern. The second dry etching processing is a batch formation process of collectively etching the organic EL layer 17R as the third organic layer, the second electrode 18B, the organic EL layer 17B as the fourth organic layer, the third electrode 21B, and the protective layer 32A. In addition, at this time, as also illustrated in FIG. 27, the sidewall insulating layer 30 is formed on the wall surface portion 25 side of the laminated structure 13B so as to cover the wall surface portion 25. Similarly to the sidewall insulating layer 30 on the wall surface portion 25 side of the laminated structure 13A, the sidewall insulating layer 30 can be formed by, for example, processing a layer formed by a CVD method, an ALD method, or the like by lithography, etching, or the like, or processing by a sidewall process or the like. In addition, the sidewall insulating layer 30 may be formed by deposition or the like at the time of dry etching during batch formation processing. The sidewall insulating layer 30 is stacked on the wall surface portion 25 side of the laminated structure 13A. Note that, in the example of FIG. 26, the pattern of the resist 81 is a stripe-shaped pattern including the arrangement region of the laminated structure 13B and extending in the Y-axis direction. In the stage of the second dry etching processing, the etched layers (organic EL layer 17G, second electrode 18B, organic EL layer 17W, third electrode 21B, and protective layer 32A) are also stripe-shaped.

Therefore, at the time of the second dry etching processing, as illustrated in FIG. 29, the pixels S adjacent to each other in the X-axis direction are cut, but the pixels S adjacent to each other in the Y-axis direction are not cut.

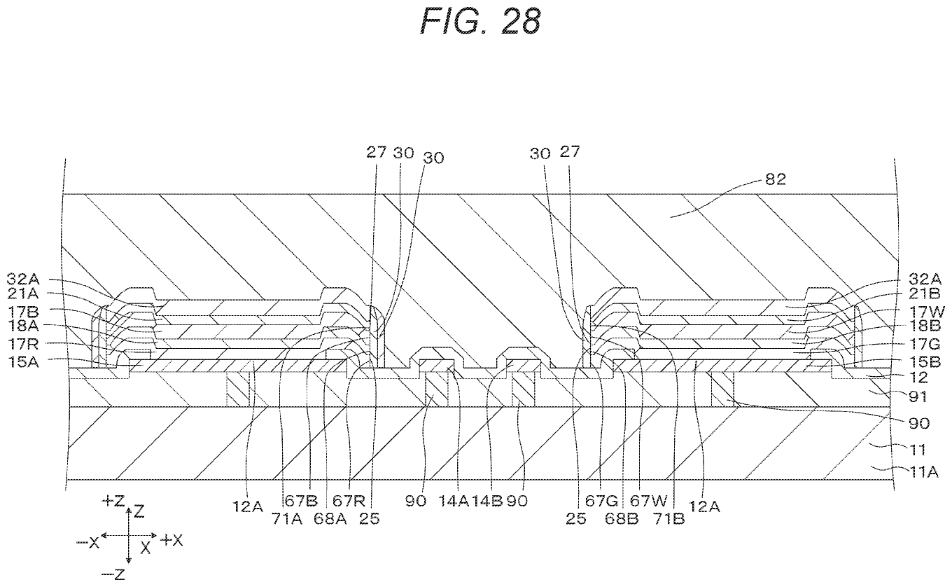

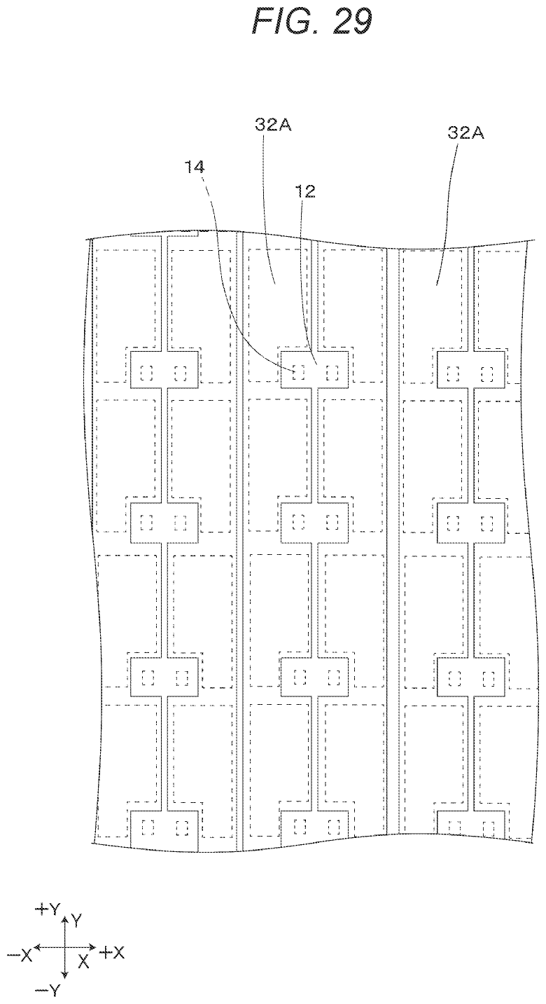

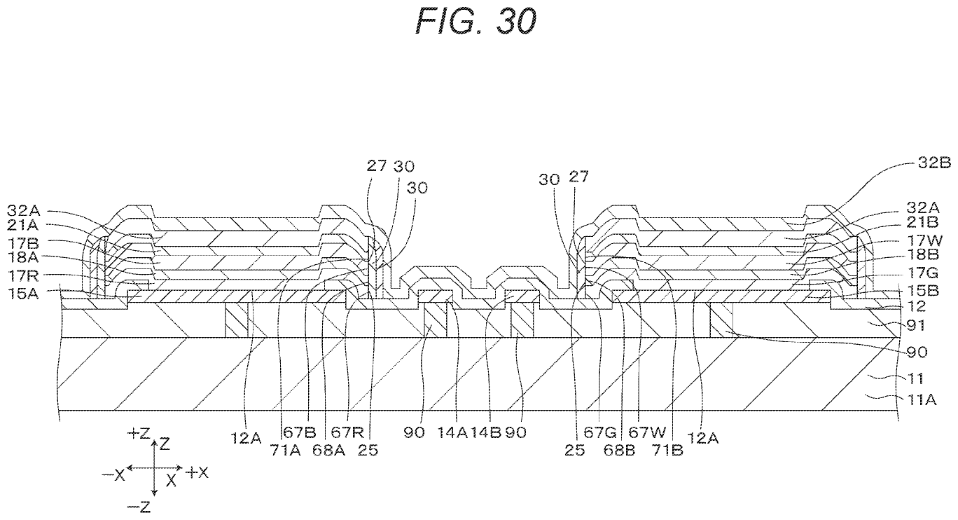

Furthermore, a resist 82 is formed on the first surface (FIG. 28), and dry etching (third dry etching processing) is performed. In the third dry etching, pixels adjacent to each other in the Y-axis direction are divided along the X-axis direction. That is, the pixels S connected in the Y-axis direction illustrated in FIG. 29 are cut by the third dry etching. At this time, the third electrodes 21A and 21B and the organic EL layers 17B and 17W are also divided for each pixel. Note that, in the third dry etching processing, the division of the second electrode 18 is avoided, and the division of the organic EL layer 17R and the organic EL layer 17G is also avoided.

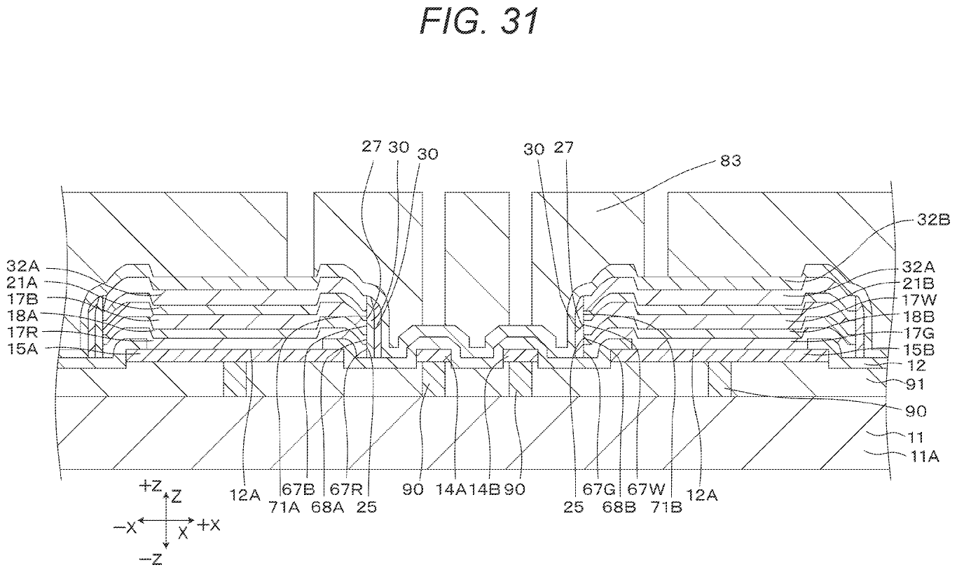

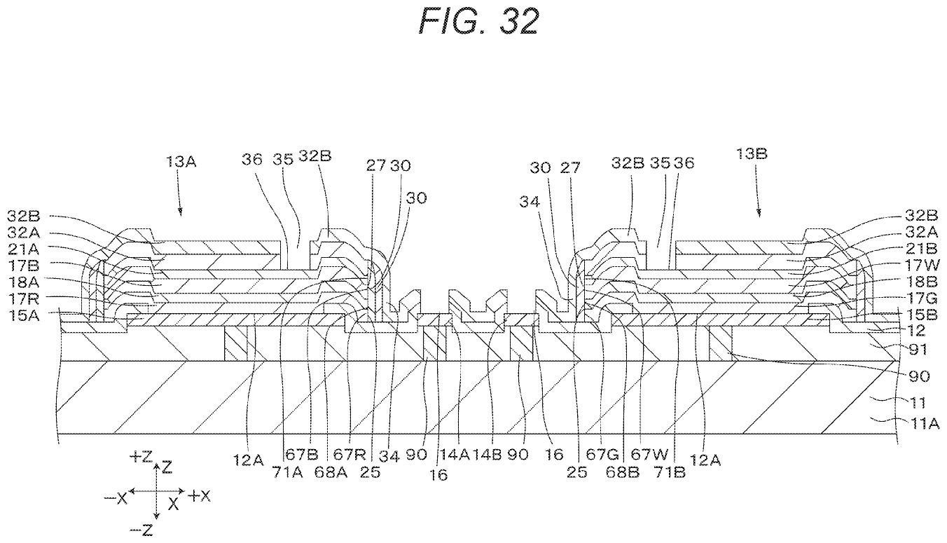

Next, as illustrated in FIG. 30, a protective layer 32B is formed on the first surface. Then, a resist 83 is formed on the protective layer 32B (FIG. 31), and dry etching (fourth dry etching processing) is performed. In the fourth dry etching processing, a connection hole 35 and a connection hole 16 on the pad 14 are formed (FIG. 32).

Furthermore, a metal layer is formed on the first surface, and patterning is performed in a pattern corresponding to the wiring 38. As a result, the wiring 38 is connected to the upper surface side of the third electrode 21 in the connection hole 35, extends from the upper surface side of the third electrode 21 along the surface of the protective layer 32B, passes through the outer surface side of the wall surface portion 25 to the drive substrate 11 side, and is connected to the pad 14.

After the wiring 38 is applied on the protective layer 32B, a filling resin layer 104 may be formed. Note that, before the filling resin layer 104 is formed, a protective layer may be formed by using a CVD method, an ALD method, or the like. A counter substrate 105 may be disposed on the filling resin layer 104. Formation of the filling resin layer 104 and arrangement of the counter substrate 105 can be appropriately formed using a method known in the prior art or the like. Thus, the display device 10A as illustrated in FIG. 3 is formed.

### 5 Application Example

### (Electronic Device)

The display devices 10A, 10B, and 10C according to the above-described embodiments may be provided in various electronic devices. Especially, this is preferably provided in an electronic viewfinder of a video camera or a single-lens reflex camera, a head-mounted display, or the like in which high resolution is required, used for enlarging near the eyes.

### Specific Example 1

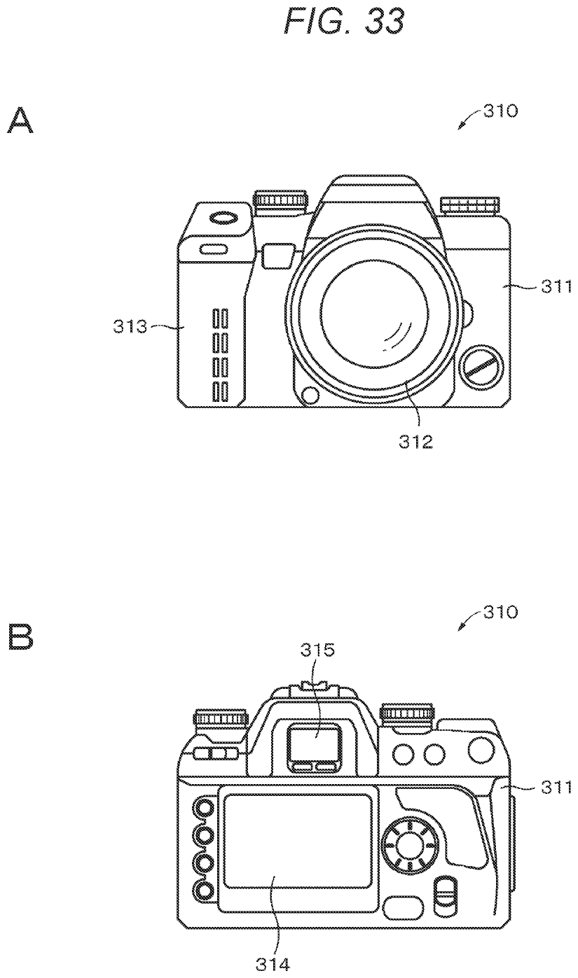

FIG. 33A is a front view illustrating an example of an external appearance of a digital still camera 310. FIG. 33B is a rear view illustrating an example of an external appearance of the digital still camera 310. The digital still camera 310 is of a lens interchangeable single-lens reflex type, and includes an interchangeable imaging lens unit (interchangeable lens) 312 substantially at the center in front of a camera main body (camera body) 311, and a grip portion 313 to be held by a photographer on a front left side.

A monitor 314 is provided at a position shifted to the left from the center of a back surface of the camera main body 311. An electronic viewfinder (eyepiece window) 315 is provided above the monitor 314. By looking through the electronic viewfinder 315, the photographer may visually confirm an optical image of a subject guided from the imaging lens unit 312 and determine a picture composition. As the electronic viewfinder 315, any of the display devices 10A, 10B, and 10C according to the above-described embodiments and modifications can be used.

### Specific Example 2

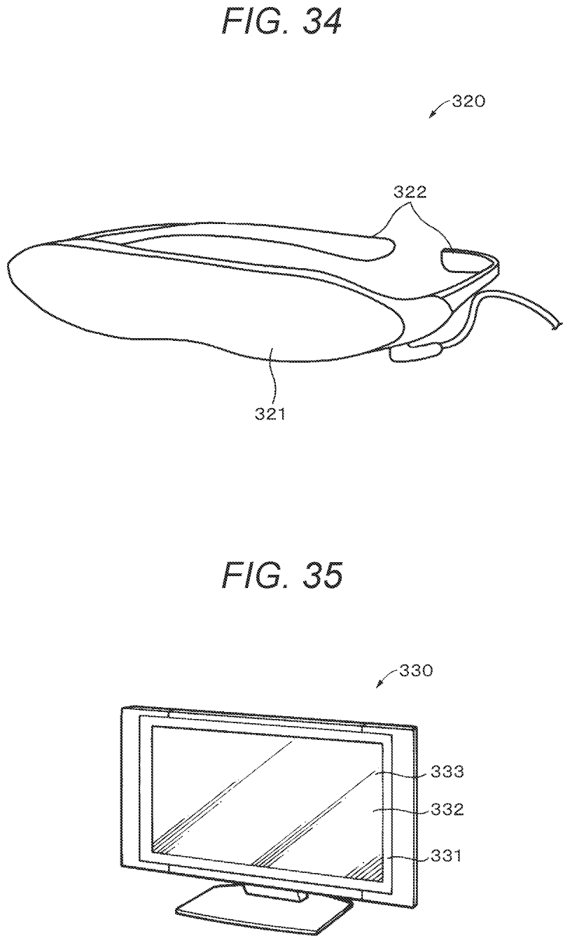

FIG. 34 is a perspective view illustrating an example of an external appearance of a head mounted display 320. The head mounted display 320 includes, for example, ear hooking portions 322 to be worn on the head of the user on both sides of a glass-shaped display unit 321. As the display unit 321, any one of the display devices 10A, 10B, and 10C according to the above-described embodiments and modifications can be used.

### Specific Example 3

FIG. 35 is a perspective view illustrating an example of an external appearance of a television device 330. The television device 330 includes, for example, a video display screen unit 331 including a front panel 332 and a filter glass 333, and the video display screen unit 331 includes any of the display devices 10A, 10B, and 10C according to the above-described embodiments and modifications.

Although the display device, the method of manufacturing the display device, and the application example according to the first to third embodiments and the modifications of the present disclosure have been specifically described above, the present disclosure is not limited to the display device, the method of manufacturing the display device, and the application example according to the first to third embodiments and the modifications described above, and various modifications based on the technical idea of the present disclosure are possible.

For example, the configurations, methods, steps, shapes, materials, numerical values, and the like described in the display device, the method of manufacturing the display device, and the application examples according to the first to third embodiments and the modifications are merely examples, and configurations, methods, steps, shapes, materials, numerical values, and the like different from those described above may be used as necessary.

The configurations, methods, steps, shapes, materials, numerical values, and the like of the display device, the method of manufacturing the display device, and the application examples according to the first embodiment to the third embodiment and the modifications described above can be combined with each other without departing from the gist of the present disclosure.

The materials exemplified in the display device, the method for manufacturing the display device, and the application examples according to the first to third embodiments and the modifications described above can be used alone or in combination of two or more unless otherwise specified.

Furthermore, the present disclosure can also adopt the following configurations.

(1) A light emitting device including:
a substrate;
a laminated structure; and
an electrode relay portion,
in which the laminated structure includes a first electrode, a first organic layer, a second electrode, a second organic layer, and a third electrode in this order on the substrate,
the second electrode is a common electrode corresponding to the first electrode and the third electrode,
a wall surface portion is formed, the wall surface portion including, at least in part, a connecting surface in which a sidewall of the first organic layer, a sidewall of the second electrode, and a sidewall of the second organic layer are connected,
a sidewall insulating layer covering at least a part of the wall surface portion is provided, and
the electrode relay portion extends from the third electrode toward the substrate, and passes over an outer surface of the wall surface portion via the sidewall insulating layer.

(2) The light emitting device according to (1),
in which positions of the sidewall of the first organic layer, the sidewall of the second electrode, and the sidewall of the second organic layer are aligned with a position of a sidewall of the third electrode on the connecting surface of the wall surface portion.

(3) The light emitting device according to (1) or (2),
in which the electrode relay portion is connected to an upper surface side of the third electrode.

(4) The light emitting device according to (1) or (2),
in which the electrode relay portion extends from an outer edge portion of the third electrode.

(5) The light emitting device according to any one of (1) to (4),
in which the first electrode and the third electrode are anodes, and
the second electrode is a cathode.

(6) The light emitting device according to any one of (1) to (5),
in which the first electrode and the third electrode are electrically separated from each other.

(7) The light emitting device according to any one of (1) to (6), further including
a display region,
in which an auxiliary electrode is provided outside the display region on the substrate, and
the second electrode is connected to the auxiliary electrode.

(8) The light emitting device according to any one of (1) to (7),
in which the sidewall insulating layer contains at least one element selected from Si, N, O, Al, Ti, and C.

(9) The light emitting device according to any one of (1) to (8),
in which the sidewall insulating layer has a multilayer structure.

(10) The light emitting device according to any one of (1) to (9),
in which an average total thickness of the sidewall insulating layer is 5 nm or more and 1 μm or less.

(11) The light emitting device according to any one of (1) to (10), further including:
a first electrode relay portion as the electrode relay portion; and
a second electrode relay portion,
in which the laminated structure further includes a fourth electrode, a third organic layer, and a fifth electrode in this order on the third electrode,
the wall surface portion has an alignment surface in which a sidewall of the third electrode, a sidewall of the fourth electrode, and a sidewall of the third organic layer are arranged along a surface direction of the connecting surface, and
the second electrode relay portion extends from the fourth electrode toward the substrate and passes over an outer surface of the wall surface portion via the sidewall insulating layer.

(12) The light emitting device according to (11),
in which the third electrode and the fourth electrode are electrically separated from each other.

(13) The light emitting device according to (11) or (12), further including
a third electrode relay portion extending from the fifth electrode toward the substrate,
in which an exposed portion to which the third electrode relay portion is connected is formed in the second electrode,
an erected surface portion rising in a direction away from the substrate with an end edge of the exposed portion as a base end is formed,
the sidewall insulating layer is further formed on at least a part of the erected surface portion, and
the third electrode relay portion passes over an outer surface of the erected surface portion via the sidewall insulating layer.

(14) A light emitting device including:
a substrate;
a laminated structure;
a first electrode relay portion; and
a second electrode relay portion,
in which the laminated structure includes a first electrode, a first organic layer, a second electrode, a second organic layer, a third electrode, a fourth electrode, a third organic layer, and a fifth electrode in this order on the substrate,
the second electrode is a common electrode corresponding to the first electrode and the third electrode,
a wall surface portion is formed, the wall surface portion including, at least in a part, a connecting surface formed by connecting a sidewall of the first organic layer, a sidewall of the second electrode, and a sidewall of the second organic layer, and an alignment surface formed by arranging at least a sidewall of the fourth electrode and a sidewall of the third organic layer along a surface direction of the connecting surface,
a sidewall insulating layer is provided on the wall surface portion,
the first electrode relay portion extends from the third electrode to the substrate,
the second electrode relay portion extends from the fourth electrode toward the substrate, and
the first electrode relay portion and the second electrode relay portion pass over an outer surface of the wall surface portion via the sidewall insulating layer.

(15) A light emitting device including:
a substrate;
a laminated structure; and
an electrode relay portion,
in which the laminated structure includes a first electrode, a first organic layer, a charge generation layer, a second organic layer, and a second electrode in this order on the substrate,
a wall surface portion is formed, the wall surface portion including, at least in part, a connecting surface in which a sidewall of the first organic layer, a sidewall of the charge generation layer, and a sidewall of the second organic layer are connected,
a sidewall insulating layer is provided on the wall surface portion, and
the electrode relay portion extends from the second electrode to the substrate and passes over an outer surface of the wall surface portion via the sidewall insulating layer.

(16) A display device including
a light emitting device according to claim 1.

(17) An electronic device including
a display device according to claim 16.

### REFERENCE SIGNS LIST

10A Display device
10B Display device
10C Display device
11 Drive substrate
14 Pad
15A First electrode
15B First electrode
16 Connection hole
17 Organic EL layer
18A Second electrode
18B Second electrode
21A Third electrode
21B Third electrode
25 Wall surface portion
27 Connecting surface
30 Sidewall insulating layer
38 Wiring
40 Auxiliary electrode
104 Filling resin layer
105 Counter substrate
116 Connection hole
117 Organic EL layer
118 Second electrode
121 Third electrode
125 Wall surface portion
127 Connecting surface
130 Sidewall insulating layer
145 Fourth electrode
147 Fifth electrode
148 Wiring
149 Wiring
219 Charge generation layer
225 Wall surface portion
227 Connecting surface
230 Sidewall insulating layer

1. A light emitting device comprising:
a substrate;
a laminated structure; and
an electrode relay portion,
wherein the laminated structure includes a first electrode, a first organic layer, a second electrode, a second organic layer, and a third electrode in this order on the substrate,
the second electrode is a common electrode corresponding to the first electrode and the third electrode,
a wall surface portion is formed, the wall surface portion including, at least in part, a connecting surface in which a sidewall of the first organic layer, a sidewall of the second electrode, and a sidewall of the second organic layer are connected,
a sidewall insulating layer covering at least a part of the wall surface portion is provided, and
the electrode relay portion extends from the third electrode toward the substrate, and passes over an outer surface of the wall surface portion via the sidewall insulating layer.

2. The light emitting device according to claim 1,
wherein positions of the sidewall of the first organic layer, the sidewall of the second electrode, and the sidewall of the second organic layer are aligned with a position of a sidewall of the third electrode on the connecting surface of the wall surface portion.

3. The light emitting device according to claim 1,
wherein the electrode relay portion is connected to an upper surface side of the third electrode.

4. The light emitting device according to claim 1,
wherein the electrode relay portion extends from an outer edge portion of the third electrode.

5. The light emitting device according to claim 1,
wherein the first electrode and the third electrode are anodes, and
the second electrode is a cathode.

6. The light emitting device according to claim 1,
wherein the first electrode and the third electrode are electrically separated from each other.

7. The light emitting device according to claim 1, further comprising
a display region,
wherein an auxiliary electrode is provided outside the display region on the substrate, and
the second electrode is connected to the auxiliary electrode.

8. The light emitting device according to claim 1,
wherein the sidewall insulating layer contains at least one element selected from Si, N, O, Al, Ti, and C.

9. The light emitting device according to claim 1,
wherein the sidewall insulating layer has a multilayer structure.

10. The light emitting device according to claim 1,
wherein an average total thickness of the sidewall insulating layer is 5 nm or more and 1 μm or less.

11. The light emitting device according to claim 1, further comprising:
a first electrode relay portion as the electrode relay portion; and
a second electrode relay portion,
wherein the laminated structure further includes a fourth electrode, a third organic layer, and a fifth electrode in this order on the third electrode,
the wall surface portion has an alignment surface in which a sidewall of the third electrode, a sidewall of the fourth electrode, and a sidewall of the third organic layer are arranged along a surface direction of the connecting surface, and
the second electrode relay portion extends from the fourth electrode toward the substrate and passes over an outer surface of the wall surface portion via the sidewall insulating layer.

12. The light emitting device according to claim 11,
wherein the third electrode and the fourth electrode are electrically separated from each other.

13. The light emitting device according to claim 11, further comprising
a third electrode relay portion extending from the fifth electrode toward the substrate,
wherein an exposed portion to which the third electrode relay portion is connected is formed in the second electrode,
an erected surface portion rising in a direction away from the substrate with an end edge of the exposed portion as a base end is formed,
the sidewall insulating layer is further formed on at least a part of the erected surface portion, and
the third electrode relay portion passes over an outer surface of the erected surface portion via the sidewall insulating layer.

14. A light emitting device comprising:
a substrate;
a laminated structure;
a first electrode relay portion; and
a second electrode relay portion,
wherein the laminated structure includes a first electrode, a first organic layer, a second electrode, a second organic layer, a third electrode, a fourth electrode, a third organic layer, and a fifth electrode in this order on the substrate,
the second electrode is a common electrode corresponding to the first electrode and the third electrode,
a wall surface portion is formed, the wall surface portion including, at least in a part, a connecting surface formed by connecting a sidewall of the first organic layer, a sidewall of the second electrode, and a sidewall of the second organic layer, and an alignment surface formed by arranging at least a sidewall of the fourth electrode and a sidewall of the third organic layer along a surface direction of the connecting surface,
a sidewall insulating layer is provided on the wall surface portion,
the first electrode relay portion extends from the third electrode to the substrate,
the second electrode relay portion extends from the fourth electrode toward the substrate, and
the first electrode relay portion and the second electrode relay portion pass over an outer surface of the wall surface portion via the sidewall insulating layer.

15. A light emitting device comprising:
a substrate;
a laminated structure; and
an electrode relay portion,
wherein the laminated structure includes a first electrode, a first organic layer, a charge generation layer, a second organic layer, and a second electrode in this order on the substrate,
a wall surface portion is formed, the wall surface portion including, at least in part, a connecting surface in which a sidewall of the first organic layer, a sidewall of the charge generation layer, and a sidewall of the second organic layer are connected,
a sidewall insulating layer is provided on the wall surface portion, and
the electrode relay portion extends from the second electrode to the substrate and passes over an outer surface of the wall surface portion via the sidewall insulating layer.

16. A display device comprising
a light emitting device according to claim 1.

17. An electronic device comprising
a display device according to claim 16.
